(19) United States
(12) Patent Application Publication
(10) Pub. No.: US 2026/0187332 A1
(43) Pub. Date: Jul. 2, 2026

(54) SIGNED DISTANCE FIELDS FOR GENERATIVE CIRCUIT LAYOUT DESIGN

(71) Applicant: NVIDIA Corporation, Santa Clara, CA (US)

(72) Inventors: Mark Jeffrey KILGARD, Austin, TX (US); David Zhao AKELEY, Sunnyvale, CA (US)

(73) Assignee: NVIDIA Corporation, Santa Clara, CA (US)

(21) Appl. No.: 19/008,265

(22) Filed: Jan. 2, 2025

(51) Int. Cl. G06F 30/392

(52) U.S. Cl. CPC G06F 30/392

(57) ABSTRACT

In various examples, systems and methods are disclosed relating to generating distance fields for generative layout design. A system can identify a signed distance field for a circuit layout, at least one sample of the signed distance field comprising a gradient of the signed distance field corresponding to a location of the sample. The system can identify a set of ridge points in the signed distance field based at least on the gradient of the at least one sample of the signed distance field. The system can generate a graph data structure using the set of ridge points, at least a subset of the set of ridge points represented as nodes in the graph data structure. The system can determine a path for the circuit layout using the nodes of the graph data structure.

### BACKGROUND

Computer-aided design (CAD) software can be used to place and route components for circuit boards. Placing virtual components for a circuit board layout involves determining the reasonably optimal positions for each component and trace routing between components while adhering to design constraints. It is challenging to efficiently perform layout and routing operations for complex circuits.

### SUMMARY

This disclosure describes systems and methods that optimize two-dimensional (2D) shape transformations in circuit board layout processes using graphics processing units (GPUs). Shape transformations are implemented by CAD software to create circuit designs for a variety of operations, including power/ground plane definition, design rule/tolerance verification, and routing, among others. Conventional general-purpose processor-based approaches are become inefficient as the number of shapes increases due to the high computational demands of performing operations such as intersection, union, subtraction, dilation, or erosion on 2D shapes. To address the limitations of conventional approaches, the techniques described herein leverage the characteristics of GPU architectures to perform efficient 2D shape transformations.

Specifically, the techniques described herein implement signed-distance fields to represent 2D shapes for traces, planes, or component footprints in a circuit board layout. Unlike conventional signed distance fields, which suffer from low detail preservations and inaccuracies with respect to adaptive sampling, the signed distance fields described herein implement additional tag values for each sample that indicate the closest path segment of one or more 2D shapes. Further, the signed distance fields described herein are generated from uniform sampling, and therefore allow merging of two or more signed distance fields for various operations including union operations, intersection operations, subtraction operations, erosion operations, and deflation operations. The signed distance fields described herein can be used to implement 2D shape transformations for circuit layouts that cannot practically be performed using conventional CPU-based techniques.

Additionally, the signed distance fields described herein can be used to implement efficient path routing between components of a circuit layout. Automatic routing in circuit board layout processes can be optimized by utilizing signed-distance fields that represent traces, planes, or component footprints. Conventional CPU-based routing algorithms struggle with the complexity of dense layouts due to their reliance on direct shape comparisons. To overcome these limitations, the signed distance fields implemented on GPUs as described herein encode gradient information that allows for the identification of ridge points, which represent potential paths between components. These ridge points can be connected to form a ridge graph, providing a network of open spaces suitable for trace routing. The techniques described herein avoid the inefficiencies of traditional CPU-based hierarchical data structures and enable accurate route determination without direct shape comparisons.

At least one aspect relates to one or more processors. The one or more processors can include one or more circuits. The one or more circuits can identify a plurality of shapes corresponding to a circuit layout. The one or more circuits can generate a signed distance field using the plurality of shapes. In non-limiting example embodiments, at least one (e.g., each) sample of the signed distance field can include an identifier of the closest shape of the plurality of shapes. The one or more circuits can modify the signed distance field according to a transformation operation and based at least on the identifier of the closest shape. The one or more circuits can generate an output corresponding to the modified signed distance field.

In some implementations, the transformation operation comprises a dilation operation or an erosion operation. In some implementations, the one or more circuits can modify the signed distance field based at least on a second signed distance field. In some implementations, the transformation operation comprises a union operation, an intersection operation, or a subtraction operation. In some implementations, the one or more circuits can generate the signed distance field such that at least one (e.g., each) sample comprises a gradient of the signed distance field corresponding to a location of the sample.

In some implementations, the gradient comprises a two-dimensional gradient for the signed distance field. In some implementations, the signed distance field is generated as a texture having a plurality of pixels. In non-limiting example embodiments, at least one (e.g., each) pixel of the plurality of pixels can correspond to a respective sample of a plurality of samples of the signed distance field. In some implementations, at least one (e.g., each) sample of the plurality of samples comprises a signed distance value encoded as a first color value, the gradient encoded as a second color value, and the identifier of the closest shape encoded as a third color value. In some implementations, the one or more circuits can generate the output to include a modified shape generated based at least on a zero-isovalue extracted from the modified signed distance field.

At least one other aspect is directed to a system. The system can include one or more processors. The system can allocate a texture having dimensions sufficient to accurately sample details of a circuit layout comprising a plurality of shapes. In one or more embodiments, the texture has sufficient dimensions to accurately and precisely sample a circuit layout corresponding to the finest level of detail manufacturable by available circuit manufacturing processes. The system can update the texture such that at least one (e.g., each) pixel comprises a first color channel indicating an absolute signed distance value relative to a corresponding shape of the plurality of shapes, and such that at least one (e.g., each) pixel comprises a gradient indicating a unit normal pointing away from the corresponding shape of the plurality of shapes. The system can allocate a stencil buffer matching the dimensions of the texture. The system can update, based on a stencil operation performed using the stencil buffer, the texture to negate the absolute signed distance value and the gradient of the at least one pixel that are located within at least one shape of the plurality of shapes.

In some implementations, the gradient comprises a first gradient value stored in a second color channel of the at least one pixel and a second gradient value stored in a third color channel of the at least one pixel. In some implementations, the at least one pixel of the texture further comprises a respective identifier of the closest segment of a shape of the plurality of shapes. In some implementations, the system can generate an updated texture by adding a bias value to the distance value of the at least one pixel of the texture to perform an erosion or dilation operation. In some implementations, the texture is a first texture. In some implementations, the system can generate an updated texture by combining the first texture with a second texture corresponding to a second signed distance field. In some implementations, the system can combine the first texture with the second texture by performing a pixel-wise max operation, min operation, or subtraction operation.

Another aspect is directed to a method. The method includes identifying, using one or more processors, a plurality of shapes corresponding to a circuit layout. The method includes generating, using the one or more processors, a signed distance field using the plurality of shapes. In non-limiting example embodiments, at least one (e.g., each) sample of the signed distance field can include an identifier of the closest shape of the plurality of shapes. The method includes modifying, using the one or more processors, the signed distance field according to a transformation operation and based at least on the identifier of the closest shape. The method includes generating, using the one or more processors, an output corresponding to the modified signed distance field.

In some implementations, the transformation operation comprises a dilation operation or an erosion operation. In some implementations, the method includes modifying, using the one or more processors, the signed distance field using a second signed distance field.

At least one aspect relates to one or more processors. The one or more processors can include one or more circuits. The one or more circuits can identify a signed distance field for a circuit layout. In non-limiting example embodiments, at least one (e.g., each) sample of the signed distance field can include a gradient of the signed distance field corresponding to a location of the sample. The one or more circuits can identify a set of ridge points in the signed distance field based at least on the gradient of the at least one sample of the signed distance field. The one or more circuits can generate a graph data structure using the set of ridge points, at least a subset of the set of ridge points represented as nodes in the graph data structure. The one or more circuits can determine a path for the circuit layout using the nodes of the graph data structure.

In some implementations, the one or more circuits can identify the set of ridge points according to a discontinuity of the gradient of at least two samples of the signed distance field. In some implementations, the signed distance field is generated as an image. In some implementations, the one or more circuits can generate a texture corresponding to the signed distance field that encodes whether at least one pixel in the image corresponds to a ridge point of the set of ridge points. In some implementations, the one or more circuits can receive an indication of a first point and a second point in the signed distance field. In some implementations, the one or more circuits can determine the path from the first point to the second point using the nodes of the graph data structure and the signed distance field.

In some implementations, the first point is a first contact of a first component of a circuit layout and the second point is a second contact of a second component of the circuit layout. In some implementations, the one or more circuits can determine the path from the first point to the second point using an A-star function. In some implementations, the one or more circuits can generate the ridge graph by generating an edge between at least two ridge points of the set of ridge points. In some implementations, the gradient comprises a two-dimensional gradient for the signed distance field. In some implementations, the one or more circuits can generate the signed distance field using the plurality of shapes such that a respective border of each shape of the plurality of shapes defined as a zero-isoline.

At least one aspect relates to a system. The system can include one or more processors. The system can generate a texture storing an augmented signed distance field for a circuit layout comprising a plurality of shapes. In non-limiting example embodiments, at least one (e.g., each) pixel of the texture can include a signed distance value and a gradient of the signed distance field corresponding to a location of the at least one pixel and a corresponding shape of the plurality of shapes. The system can generate, using the signed distance value and the gradient of the at least one pixel of the texture, a ridge texture having a respective pixel value indicating whether a ridge point is present at each pixel of the texture. The system can identify an additional point to include in the ridge texture. The system can iteratively update, using the gradient of adjacent pixels of the texture the ridge texture to rasterize a line from the additional point to at least one second pixel in the ridge texture.

In some implementations, the system can generate a ridge point graph using the ridge texture, wherein the at least one pixel comprises a positive value is represented as a node in the ridge point graph. In some implementations, the additional point is represented as a node in the ridge point graph. In some implementations, the system can remove at least one node from the ridge point graph by combining at least two edges in the ridge point graph connected to the at least one node. In some implementations, the system can generate a path from a start point to an end point using the ridge texture.

At least one aspect is related to a method. The method can include identifying, using one or more processors, a signed distance field for a circuit layout. In non-limiting example embodiments, at least one (e.g., each) sample of the signed distance field includes a gradient of the signed distance field corresponding to a location of the sample. The method can include identifying, using the one or more processors, a set of ridge points in the signed distance field based at least on the gradient of the at least one sample of the signed distance field. The method can include generating, using the one or more processors, a graph data structure using the set of ridge points. At least a subset of the set of ridge points are represented as nodes in the graph data structure. The method can include determining, using the one or more processors, a path for the circuit layout using the nodes of the graph data structure.

In some implementations, the method includes identifying, using the one or more processors, the set of ridge points according to a discontinuity of the gradient of at least two samples of the signed distance field. In some implementations, the signed distance field is generated as an image. In some implementations, the method includes generating, using the one or more processors, a texture corresponding to the signed distance field that encodes whether at least one pixel in the image corresponds to a ridge point of the set of ridge points. In some implementations, the method includes receiving, using the one or more processors, an indication of a first point and a second point in the signed distance field. In some implementations, the method includes determining, using the one or more processors, the path from the first point to the second point using the nodes of the graph data structure and the signed distance field.

The processors, systems, and/or methods described herein can be implemented by or included in at least one of a control system for an autonomous or semi-autonomous machine, a perception system for an autonomous or semi-autonomous machine, a system for performing simulation operations, a system for performing digital twin operations, a system for performing light transport simulation, a system for performing collaborative content creation for 3D assets, a system for performing deep learning operations, a system for performing generative AI operations using a large language model, a system for performing generative AI operations using a video language model, a system implemented using an edge device, a system implemented using a robot, a system for performing conversational AI operations, a system for generating synthetic data, a system incorporating one or more virtual machines (VMs), a system implemented at least partially in a data center, or a system implemented at least partially using cloud computing resources.

### BRIEF DESCRIPTION OF THE DRAWINGS

The present systems and methods for implementing shape operations according to signed distance fields are described in detail below with reference to the attached drawing figures, wherein:

FIG. 1 is a block diagram of an example system for implementing shape transformation and routing processes according to augmented signed distance fields, in accordance with some embodiments of the present disclosure;

FIGS. 2A, 2B, and 2C, and depict example diagrams showing resulting outputs of shape dilation and erosion techniques implemented using augmented signed distance fields, in accordance with some embodiments of the present disclosure;

FIGS. 3A, 3B, 3C, 3D, and 3E depict example diagrams showing outputs of shape Boolean operations implemented using augmented signed distance fields, in accordance with some embodiments of the present disclosure;

FIGS. 4A and 4B depict example diagrams showing how gradients of augmented signed distance fields are used to generate a ridge graph for circuit routing, in accordance with some embodiments of the present disclosure;

FIG. 5 is a flow diagram of an example method for implementing shape transformation operations using augmented signed distance fields, in accordance with some embodiments of the present disclosure;

FIG. 6 is a flow diagram of an example method for implementing routing operations using augmented signed distance fields, in accordance with some embodiments of the present disclosure;

FIG. 7 is a block diagram of an example computing device suitable for use in implementing some embodiments of the present disclosure; and

FIG. 8 is a block diagram of an example data center suitable for use in implementing some embodiments of the present disclosure.

### DETAILED DESCRIPTION

Circuit board layout processes involve arranging the footprints of different components while satisfying the tolerances specified in design rules. These design rules ensure that the circuit board operates as intended once constructed, and typically involves minimum tolerances for the placement of components and traces on the circuit board. Automatic circuit board design processes use algorithms to automatically place and route components on a virtual circuit board so that their virtual footprints satisfy such constraints.

Two-dimensional (2D) shape processing is one class of operations used in performing automatic component placement and routing. For example, modifying the outlines of 2D shapes is a useful operation when planning power or ground planes on a circuit board following component placement. Such operations can include intersection operations, union operations, subtraction operations, dilation operations, or erosion operations for one or more 2D shapes. These operations can be used, for example, to create or modify ground planes on a circuit board to comply with various design rules.

However, conventional approaches for 2D shape processing are CPU-based and cannot practically or accurately process certain topological changes in 2D shapes common to circuit board layout processes. For example, dilation or erosion operations performed using conventional CPU-based approaches demand numerically challenging computational geometry algorithms involving boundary representations that are not straightforward to parallelize. These issues are pronounced in the field of circuit board layouts due to the increased need for accuracy and precision for dense circuit boards with thousands of components and connections.

To address these issues, the techniques described herein implement signed-distance fields to represent 2D shapes for traces, planes, or component footprints in a circuit board layout. Unlike conventional signed distance fields, which suffer from low detail preservations and inaccuracies with respect to adaptive sampling, the signed distance fields described herein implement additional tag values for each sample that indicate the closet path segment of one or more 2D shapes. Further, the signed distance fields described herein are generated from uniform sampling, and therefore allow merging of two or more signed distance fields for various operations including union operations, intersection operations, subtraction operations, erosion operations, and deflation operations.

As the signed distance fields are highly parallelizable data structures, the techniques described herein are not limited to CPU-based environments like traditional circuit board layout operations. Instead, the techniques described herein can be implemented on one or more graphics processing units (GPUs) to improve performance and reduce computational inefficiencies even when processing circuit layouts with tens of thousands of components and connections.

The signed distance fields described herein can be used to route paths between points of interest in a circuit board layout. To do so, the signed distance field gradient can be analyzed to identify ridge points, which represent locations where the signed distance field appears discontinuous. These discontinuous regions correspond to open locations that are not occupied by 2D shapes in the signed distance field. Identified ridge points can be connected by proximity to construct a ridge graph. The ridge graph can be augmented to reduce discontinuities by generating edges that follow the apparent discontinuities in the signed distance field gradients.

Once generated, the ridge graph defines a network of connected edges that are not occupied by any 2D shape in the circuit board layout. Routing algorithms can be used to generate paths between points of interest in the ridge graph, which can be adapted to routes for traces or planes for a circuit board layout. Unlike conventional, CPU-based approaches that rely on hierarchical data structures to perform routing, the techniques described herein are parallelizable and accurately determine viable routes between components or structures in a circuit layout without direct comparisons between neighboring shapes.

The system 100 can be utilized to generate augmented signed distance fields 110, which be used to perform shape 104 transformation operations and routing operations for circuit layouts indicated in layout data 112. The system 100 is shown as including a data processing system 102, layout data 112, at least one modified signed distance field 120, and routing data 124. The layout data 112 is shown as including or otherwise being associated with at least one image 113. The data processing system 102 includes one or more shapes 104, a signed distance field generator 108 (sometimes referred to as an “SDF generator 108” or an “augmented SDF generator 108”), at least one signed distance field 110 (sometimes referred to as an “augmented signed distance field 110”, an “SDF 110”, or an “augmented SDF 110”), a shape transformer 118, and a routing generator 122. Although shown as being external to the data processing system 102, the layout data 112, the modified signed distance field 120, modified shapes 121, and/or the routing data 124 may be stored in memory of the data processing system or provided to one or more external systems or processes.

The data processing system 102 can include any type of computing device that can perform layout operations for circuit boards. For example, the data processing system 102 may be computer that executes computer-aided design (CAD) software. The data processing system 102 may include, but is not limited to, one or more personal computers, a tablet device, a laptop, a smartphone device, a server in communication with one or more client devices, or a distributed computing environment, among others. The data processing system 102 can receive or otherwise identify layout data 112 from one or more processes, external computing devices, network requests, regions of memory of the data processing system 102, or other sources of information.

The layout data 112 may be generated by and received/identified from CAD software. The layout data 112 can include or may represent a layout for one or more printed circuit boards (PCBs). The layout data 112 can identify locations for component placement, interconnections, and routing paths. The layout data 112 can include information identifying one or more circuit components 113 and corresponding footprint data 114 (sometimes referred to herein as “footprint(s) 114”) for the one or more circuit components 113. Information for each component 113 can include or be associated with location data (e.g., relative or absolute location information for the component 113 in the PCB layout), which may include the location, orientation, and size/footprint of each component 113. As used herein, components 113 (and the footprints 114 that correspond thereto) can represent electrical components (e.g., resistors, capacitors, inductors, transistors, integrated circuits, etc.), traces, vias, drill holes, power/ground planes, and/or connectors, among others that are positioned in corresponding locations on a circuit layout. In some implementations, the layout data 112 and/or the footprint data 114 can include information specifying the location and orientation of the one or more components 113, including traces, ground/power planes, or electrical contacts, among others.

Different components 113 identified within the layout data 112 can be represented with distinct footprints 114, which can reflect size, dimensions, area, and portions of a corresponding component 113 that contact the PCB. A footprint 114 can define the area that the component 113 physically occupies on the PCB. In some implementations, the footprint 114 may be larger than the actual component 113 to ensure that design rules for the PCB are not violated during component 113 placement. In such implementations, the footprint 114 can be a region of the PCB dedicated to the corresponding component 113 and which cannot be occupied by any other component 113. The footprints 114 for each component may be stored in association with a corresponding identifier of the component in the layout data 112. In implementations where the data processing system 102 executes CAD software, the data processing system 102 can modify the layout data 112 (e.g., modify component positions, orientations, or properties) in response to corresponding interactions with graphical user interface(s) of the CAD software.

In some implementations, the layout data 112 may correspond to other sources of vector information. For example, the layout data 112 may include information/layout corresponding to computational lithography for chip mask design, autonomous navigation, and/or vector graphics rendering. In such implementations, rather than including components 113 that correspond to circuit elements, traces, or power/ground planes, the layout data 112 can include footprints for mask features for lithography, street maps or warehouse layouts, or 2D vector graphics assets such as fonts or illustrations. This information may be processed in a similar manner to the example techniques described herein with respect to processing circuit layouts.

The data processing system 102 can access the layout data 112 to perform various 2D shape operations, including transformation operations and routing operations. To do so, the data processing system 102 can convert the footprints 114 of the components 113 of the layout data into one or more shapes 104 stored in memory of the data processing system 102. Converting the footprints 114 into shapes can include generating one or more filled paths for each component 113 in the layout information and storing the data of each path in the memory of the data processing system 102. Each filled path can be a set of connected curved or straight segments that form a closed loop (for filled areas) or an open outline. Each shape 104 can include vertices and one or more edges connected to the vertices to define at least one outline of the shape 104 defined in a multi-dimensional (e.g., 2D, 3D) space corresponding to the layout 112 of the circuit. In some implementations, a shape 104 can include multiple closed loop paths that represent holes or openings in a shape 104. In such implementations, the interior paths representing holes or openings can have a different direction than those that represent the outer boundary of the shape 104.

In some implementations, the layout data 112 can store a representation of the circuit layout (or any other 2D layout such as lithography layouts, street maps or warehouse layouts, or 2D vector graphics) as a vector image, with the footprint 114 of each component 113 being stored as a vector graphic or in a vector format (e.g., as a shape 104). The shapes 104, as described herein, can be stored as a piece-wise continuous filled path. In such implementations, the data processing system 102 can directly retrieve the vector format footprint 114 of each component 113 as a piece-wise continuous filled path representation and store the filled path as a corresponding shape 104. In some implementations, the layout can be defined as an image with one or more layers, where each layer comprises a region of pixels representing the footprint of a respective component 113. In such implementations, the data processing system 102 can use a vectorization process or an image tracing process to convert the pixels representing each footprint 114 into a corresponding filled path representation.

In some implementations, the data processing system 102 can convert the layout data 112 into a vector image or vector data in memory of the data processing system, with each footprint 114 converted into a respective shape 104 and represented as a filled path. The vector image/vector data can be accessed by the components of the data processing system 102 to perform further operations, including performing transformation operations for the shapes 104 and determining automatic routing paths between shapes 104.

The data processing system can execute the SDF generator 108 to generate one or more augmented signed distance fields 110 representing the shapes 104 extracted/retrieved from the layout data 112. The SDF generator 108 can include software, hardware, or combinations of hardware and software. To generate an augmented signed distance field 110, the SDF generator 108 can access application programming interfaces (APIs) or function calls corresponding to one or more graphics processing units (GPUs) to generate/allocate a GPU texture representing the layout 112 corresponding to the shapes 104. The SDF generator 108 access one or more GPU rasterizer functions to translate input shapes 104 extracted from the layout data 112 into one or more augmented signed distance fields 110, which can be stored in represented as a GPU texture in memory of the one or more GPUs. In one or more non-limiting example embodiments, at least one (e.g., each) pixel of the GPU texture can be referred to as a corresponding sample 115, such that the augmented signed distance field 110 can be represented as a square or rectangular grid of samples 115.

A signed distance field is a representation of a two-dimensional region including a grid of scalar values, where each value in the grid represents the signed distance from that point in the grid to a nearest boundary point of a shape 104. A positive scalar value can indicate that the sample 115 is outside the shape, while a negative value can indicate that the sample 115 is inside the shape. The magnitude of the value corresponds to the distance (e.g., the Euclidean distance in pixel/sample space) from the respective sample 115 and the closet shape 104 boundary. Samples 115 positioned on the boundary of a shape can have an SDF value of zero. Samples 115 positioned on the boundary of a shape can sometimes be referred to as “0-isoline values” or “on the 0-isoline.” The 0-isoline effectively delineates the precise extent of the shape within the SDF grid. When represented as a GPU texture, the distance scalar value (sometimes referred to herein as the “signed distance field value” or the “SDF value”) can be stored as a pixel value (e.g., one of a red, green, blue, or alpha values) of the corresponding sample 115.

The SDF generator 108 can use the shape 104 data and the layout data 112 (which can indicate the positions and orientation of each shape 104) to generate an augmented signed distance field 110. The augmented SDF 110 includes additional information in each sample 115. At least one (e.g., each) sample 115 in an augmented SDF 110 can further store a 2D gradient vector indicating the direction from that point to the nearest boundary in addition to the signed distance value. The 2D gradient values can be used by the data processing system 102 (or the components thereof) to generate routes (e.g., routing data 124) between shapes 104 represented in the augmented SDF 110. When represented as a GPU texture, the x and y components of the 2D vector can be stored as a color or alpha channel (e.g., one of a red, green, blue, or alpha values) of the corresponding sample 115.

In some implementations, at least one (e.g., each) sample 115 in the augmented SDF 110 includes a tag value that identifies a path segment of the shape 104 closest to that sample 115 in the augmented signed distance field 110. The tag information can be stored as a numerical identifier, which may uniquely correspond to the segment or link to which the sample 115 is closest. In some implementations, the tag value can additionally or alternatively identify the shape 104 to which the sample 115 is closest in the augmented SDF 110. The tag values included in each sample 115 can be useful in determining a viable routing between different components, for example, when identifying ridge points (e.g., ridge points 126) as described in further detail herein.

Generating the augmented SDF 110 can include storing information about the footprints 114 of at least one (e.g., each) component 113 in one or more regions of memory of the data processing system 102. For example, this may include storing the positions and identifiers associated with vertices, paths, or segments of a shape 104 from the layout data 112 in one or more data structures in memory of the data processing system 102. The position information and identifiers can be used to populate each of the samples 115 of the augmented SDF 110 according to the techniques described herein.

To generate an augmented SDF 110, the SDF generator 108 can access path data of each shape. As described herein, at least one (e.g., each) of the shapes 104 can be represented as one or more paths C that are piecewise continuous. An interval of the piecewise representation can be referred to as a “link” of the path C. In this representation, a single point can represent a valid link, as this enables valid computation of distances between points and C1-discontinuities (e.g., joints, cusps) of a path C. The SDF generator 108 can allocate a depth buffer 117 for generating the augmented SDF 110 and use one or more distance stroking operations to rasterize the paths C of each shape 104 as corresponding SDF textures for the augmented SDF 110. These distance stroking operations assign SDF samples a depth value proportional to the sample's distance away from the stroke center. The depth buffer 117 ensures only the SDF information (signed distance, gradient, and/or tag) with the minimum depth is recorded for an SDF sample.

In at least one embodiment, for each link L of a piecewise-continuous path C of a shape 104, the SDF generator 108 can define a distance stroke operation to update a depth buffer 117 of one or more GPUs of the data processing system 102 (or in communication with the data processing system 102). The depth buffer 117 may be allocated in one or more regions of memory of one or more GPUs, and the parameters of the distance stroking operation can be defined using one or more APIs or low-level driver function calls of the one or more GPUs. The parameters of the distance stroking operation can include a stroke radius r, which can define radius of the stroke or the distance from the center of the path to the outer edge of the stroke, a center distance value v_{c}, which indicates the distance from the viewer to the center of the path link being drawn, a side distance value vs, which indicates the distance from the viewer to the sides of the stroke (e.g., an amount of taper from the viewer), a center depth value z_{c}, which indicates the depth value at the center of the path, a side depth value zs, which indicates depth value at the sides of the stroke, and in some implementations link pen width modulation sequences MLA and MLB (which may be uniformly set to “1” if not defined).

The SDF generator 108 can execute the distance stroking operation(s) to generate the augmented SDF 110 for one or more shapes 104. In executing the stroking operation(s), if the effective stroke radius is non-positive, the operation can be skipped. The SDF generator 108 can quantize each link L of the path C into a sequence of control points, such that the link L=l₀, l₁, . . . , l_{w}. The control points l₀, l₁, . . . , l_{w} are selected such that they closely approximate the original path C and are not necessarily uniformly selected. A corresponding sequence of unit normal values N₀, N₁, . . . , N_{w} can be determined based on the path C for each of the control points. The SDF generator 108 can define a quantized offset curve A=a₀, a₁, . . . , a_{w} such that aᵢ=lᵢ+rM^{LA}Nᵢ and a quantized B=b₀, b₁, . . . , b_{w} such that bᵢ=lᵢ−rM^{LB}Nᵢ.

The SDF generator 108 can then execute the distance stroking operation between the link L and the quantized offset curve A to rasterize a triangle strip connecting L and A, such that the vertices L are assigned a distance value attribute of v_{c} and the depth of z_{c}, and with the vertices on A assigned a distance value attribute of vs and a depth value of zs. The same approach can then be repeated using the quantized offset curve B rather than A. The resulting rasterized samples can be analyzed to determine the parameters for each sample 115 of the augmented SDF 110. The SDF generator 108 can assign the distance value component (e.g., a color channel such as the red channel) of the rasterized samples 115 by interpolating the distance value attribute of the operation. The SDF generator 108 can assign the gradient component (e.g., a color channels such as the green/blue channels) of the rasterized samples 115 by determining the gradient of the interpolated distance value and/or by interpolating the effective unit normal. In some implementations, the SDF generator 108 can assign the tag value component (e.g., a color channel such as the alpha channel) of the rasterized samples 115 to an identifier of the link L of the path C of the shape 104.

In generating the augmented SDF 110, prior to executing the distance stroking operation, the SDF generator 108 can initially clear or assign to the depth buffer 117 a value of “+1”, for example, using one or more APIs or driver functions of the one or more GPUs. The SDF generator 108 can then set the depth test for the distance stroking operation to accept incoming samples with lower depth than the resident sample. The SDF generator 108 can then clear the color component values corresponding to distance (e.g., red) to a maximum distance value B+, clear the color component values corresponding to the gradient (e.g., green, blue) to zero (e.g., indicating a zero-vector), and clear the tag values to an arbitrary value indicating that a closest link has not yet been assigned (e.g., a sentinel tag value).

To generate the augmented SDF 110, the SDF generator 108 can then execute the distance stroking operation for each link L of each path C of each shape 104. Example parameter values that may be used to generate the augmented SDF 110 may include r=B₊, v_{c}=0, vₛ=B+, z_{c}=0.5, and zₛ=1. This results in the interpolated distance value v being a monotonic-increasing function of the interpolated depth z, such that v=(2B₊) (z−0.5). As such, a “less than” comparison between two depth samples provides the same result as comparing the two corresponding distance value samples (excluding the effects of rounding error). In cases where there are multiple incoming samples for one pixel (e.g., multiple shapes), the less-than depth test ensures that the sample with the lowest distance value remains. In some implementations, the pen width modulation sequences can be used to implement various “stroking styles” such as miters. A default value of “1” may be used to implement round joints or caps, and alternate sequence can be used to implement non-standard distance metrics. Parameters for the distance stroking operation, including nay pen width modulation sequences, can be specified via one or more configuration settings of the data processing system 102, which may be provided or modified by an operator of the data processing system 102 or received from an external computing system, in some implementations.

To apply the proper sign to the distance value of each sample 115 in the augmented SDF 110 (which indicates whether a sample 115 is located within or outside a shape 104), a stencil buffer 111 and stencil operation can be implemented. The SDF generator 108 can allocate a stencil buffer 111 to determine a sample 115 is located within a shape 104. The distance value of each sample 115 identified as being located within a shape 104 can have their corresponding distance and gradient values negated (e.g., by multiplying by “−1”).

To allocate the stencil buffer 111, the SDF generator 108 can access APIs or function calls corresponding to the one or more GPUs of the data processing system 102 to reserve at least one contiguous block of memory within the address space of the one or more GPUs for performing stencil operations. The stencil buffer 111 can be allocated to include corresponding set of stencil samples 116, with each stencil samples 116 corresponding to a respective pixel of a rasterization of the layout data 112 and corresponding to a respective sample 115 of the augmented SDF 110. At least one (e.g., each) stencil sample 116 in the stencil buffer 111 can include one or more numerical values that may be manipulated at the bit-level by various stencil operations described herein.

For example, the stencil buffer 111 can be allocated such that a predetermined number of bits in each stencil samples 116 are dedicated to a winding number for the corresponding stencil sample 116. In some implementations, the bits corresponding to the winding number can be the W least-significant bits in the stencil sample 116. In one example, the winding number bits W may be selected as the six least-significant bits in each stencil sample 116. However, it should be understood that any portion of each stencil sample 116 may be used to represent the winding number for the corresponding sample. The stencil buffer 111 can be allocated such that each stencil sample 116 of the stencil buffer 111 respectively corresponds to a respective pixel of the circuit image extracted/retrieved from the layout data 112. The shapes 104 can be stored in association with location/orientation information (e.g., for each vertex/edge) such that the position(s) of each shape can be mapped to corresponding stencil sample(s) 116 of the stencil buffer 111 (e.g., through rasterization, etc.).

The SDF generator 108 can execute one or more stencil operations to determine whether each stencil sample 116 is positioned within or outside of a shape 104. The stencil operations can include “stencil” and “cover” operations performed for each shape 104. As described herein, each shape 104 can be defined as a piece-wise continuous filled path C, and each interval of the piecewise representation of the path C can be referred to as a link L. The SDF generator 108 can execute a stencil operation to calculate a respective winding number for each stencil sample 116 with respect to the path C (e.g., the shape 104 for which the stencil operation is being performed). Bits of the stencil sample 116 used for the winding number may be referred to as the winding number bits W. The winding number can be calculated such that the winding number bits W of each stencil sample 116 are incremented and wrapped.

Various configuration operations for the stencil operation, including configuring masks or other aspects of the stencil operation, can be performed by accessing one or more APIs or low-level driver functions of the one or more GPUs storing the stencil buffer 111. The SDF generator 108 can execute the stencil operation to update the winding number bits of each stencil sample 116. To ensure that only the winding number bits W of the stencil sample 116 are modified, the SDF generator 108 can access one or more APIs for driver functions of the one or more GPUs to update a stencil write mask for the stencil buffer 111. A stencil write mask can be a bit mask that allows selective modification of bits within each stencil sample 116 during a stencil operation.

The SDF generator 108 can update the winding number bits W of each with an incremented-and-wrapped winding number for a given shape 104 by rasterizing triangles extending from a fill pivot point p_{f}. The fill pivot point pₛ can be selected as a point positioned within and roughly approximate to the center of the corresponding shape 104. In some implementations, the fill pivot point pₛ can be specified as part of the footprint data 114. In some implementations, the SDF generator 108 can automatically determine the fill pivot point pf based on the relative location of each vertex and/or link of the patch C corresponding to the shape 104. The fill pivot point p_{f} can be used as a central vertex of a sequence of triangles, or a triangle fan, which extend outward toward the edges of the path C and are rasterized to update the winding number bits W of each stencil sample 116 in the stencil buffer 111.

Rasterizing the triangle fan can include defining the vertices of the triangle fan such that the triangles collectively approximate the footprint 114 of the component 113 corresponding to the shape 104. As noted above, a given shape 104 can be defined as a piecewise continuous path C including a number of links L. To generate the triangles for the triangle fan, the SDF generator 108 can quantize each link L of the path C into a sequence of control points, such that the link L=l₀, l₁, . . . , l_{w}. The control points can be the same control points used to generate the initial augmented signed distance field 110, as described herein.

The SDF generator 108 can then automatically generate/define a set of triangles (e.g., a triangle fan) that extend from the fill pivot point p_{f} to the control points l₀, l₁, . . . , l_{w}. The set of triangles can be defined such that the fill pivot point p_{f} as defined the center vertex of each triangle and the control points as the outer vertices of the fan. In this arrangement, each triangle can share at least one side with at least one other triangle forming the triangle fan. Each triangle can be defined with the fill pivot point p_{f} as the first vertex and corresponding control points as second and third vertices. The order of the second and third vertices can follow the direction of the path C. In some implementations, a portion of a path C defining the outer boundary of a shape 104 can have a clockwise direction, and a portion of a path defining an inner boundary of a shape 104 (e.g., an inner hole, etc.) can have a counterclockwise direction.

The order in which the vertices of a triangle are specified can indicate whether a triangle has a clockwise (or positive) orientation or a counterclockwise (or negative) orientation. The order of the control points can be selected such that a triangle fan defined for the outer path C of a shape 104 results in positively oriented triangles and such that a triangle fan defined for an inner path of a shape 104 (if any) results in negatively oriented triangles. Defining both positively and negatively oriented triangles for different types of paths enables the winding number of a sample 115 to correctly reflect whether the sample 115 is positioned within the shape 104, as described in further detail herein. The SDF generator 108 can generate/define the triangles in memory of the one or more GPUs using one or more APIs or driver functions of the one or more GPUs that store the stencil buffer 111. The position of the triangles can correspond to the position of the shape 104 to which they correspond.

The SDF generator 108 can then rasterize each of the triangles for the shape 104 according to the stencil operation in the stencil buffer 111. Rasterizing the triangles can include executing one or more rasterization functions of the API(s)/drivers of the one or more GPUs and can cause the winding number of each stencil sample 116 of the stencil buffer 111 to be updated. Pixels (stencil samples 116) identified as falling within a given triangle are processed by the one or more GPUs of the data processing system 102 using the stencil operation, to increment-and-wrap the winding number bits W for each stencil sample 116 that is covered by a positively oriented triangle and decrement the winding number bits W for each stencil sample 116 that is covered by a negatively oriented triangle. The increment-and-wrap operation causes the winding number bits to “wrap around” to the minimum value if incrementing the bits would exceed the maximum allowed value of the winding number bits W. The stencil operation has results in each stencil sample 116 storing in its winding number bits W the winding number modulo 2″ of that stencil sample 116 location with respect to the corresponding path C.

Once the stencil operation has been performed, each sample 115 is populated with a winding number that accurately reflects whether the stencil sample 116 is positioned within a corresponding shape 104. The SDF generator 108 can then execute a cover operation for the stencil buffer 111 to only pass stencil samples 116 having a winding number that indicates the stencil sample 116 is in the interior of a shape 104. The cover operation for the stencil buffer can include generating/defining one or more triangles that are large enough to cover at least all stencil samples 116 modified by the prior stencil operation for the path C to perform a stencil test. The cover operation implemented by the SDF generator 108 can pass all stencil samples 116 that have a nonzero winding number, and subsequently reset the winding number bits of these passing samples to zero.

Assuming the cover operation for a path C follows the stencil operation for C, this has the effect of passing exactly one stencil sample 116 for each stencil sample 116 position on the interior of the filled path C, as defined by the fill rule “nonzero winding number modulo 2^{W}”, and resetting the winding number bits of all such samples to zero. Note in particular that if W=1, then each sample's winding number bit is set to 1 if and only if the true winding number is odd. In other words, the winding number bit acts as an “is in interior” bit with respect to the shape 104 defined by filling C with an even-odd fill rule. For each passed stencil sample 116, the SDF generator 108 can negate the distance value (e.g., stored in a respective color channel) of the corresponding sample 115 of the augmented SDF 110, completing generation of the augmented SDF 110.

Once the augmented SDF 110 has been generated, data processing system 102 can execute the shape transformer 118 and/or the routing generator 122 to perform shape transformation operations and/or routing operations, respectively, using the augmented SDF 110. Examples of shape transformation operations include dilation operations, erosion operations, or Boolean operations such as union, intersection, or exclusive-OR (XOR), among others. The shape transformer 118 can include hardware, software, or combinations of hardware and software. The shape transformer 118 can access one or more augmented SDFs 110 to perform various operations described herein.

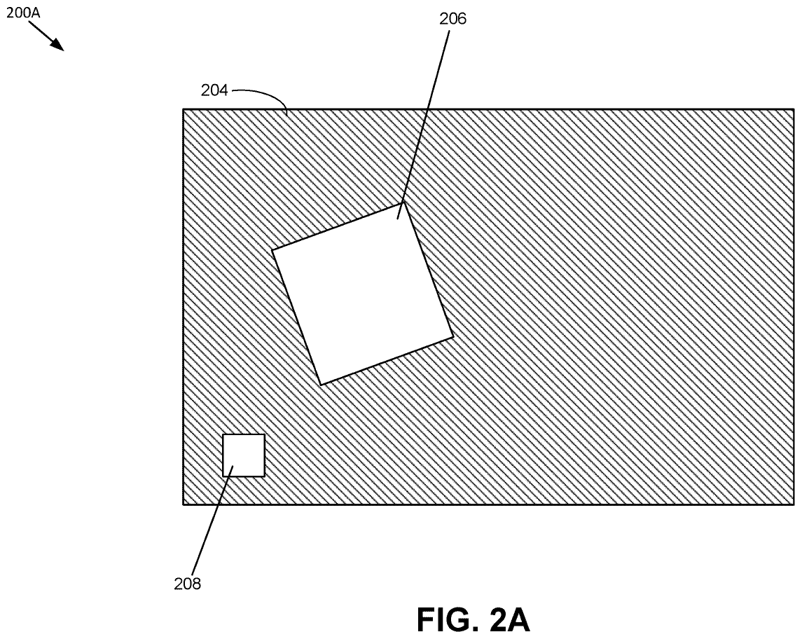

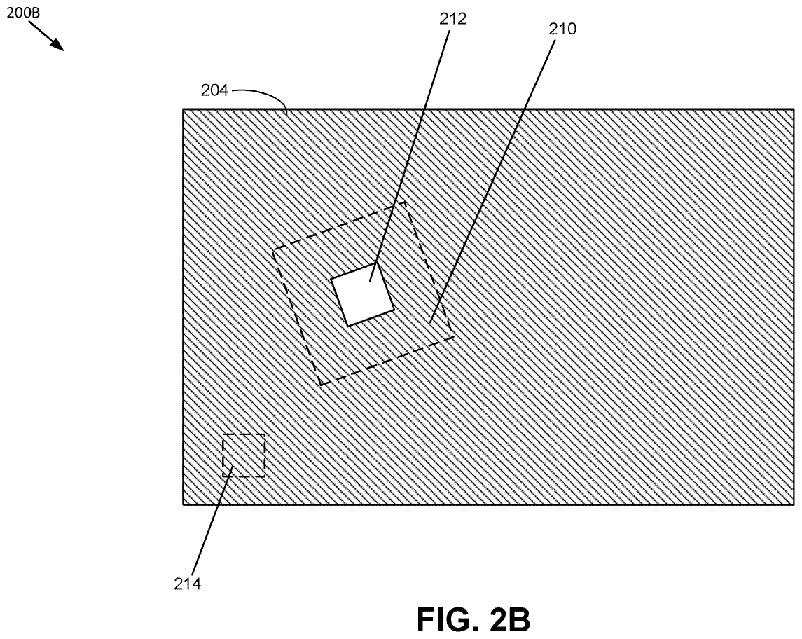

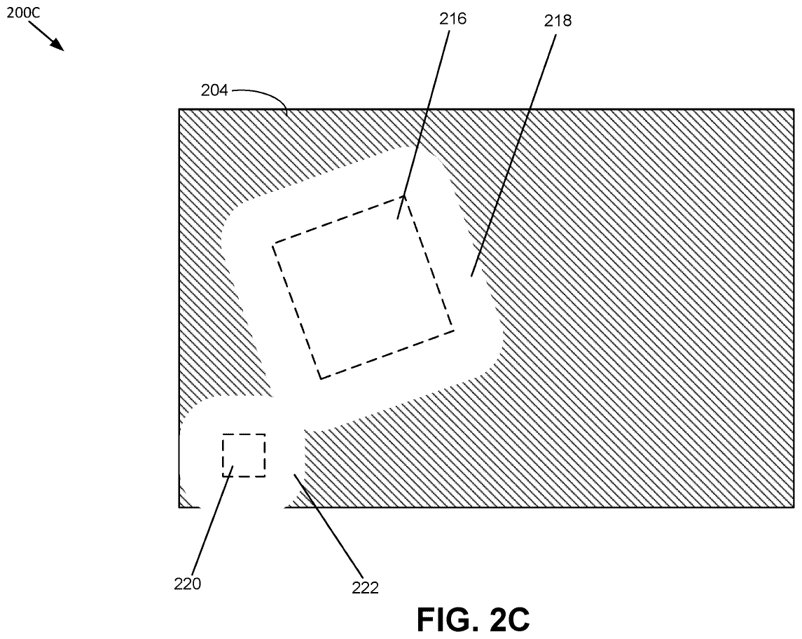

The shape transformer 118 can implement erosion and dilation operations, examples of which are depicted in FIGS. 2B and 2C, respectively, by adding or subtracting constant bias values from the distance values of the augmented SDF 110. In some implementations, the shape transformer 118 can generate a bias by generating a grid of constant bias values b in memory of the one or more GPUs, which can correspond to the same dimensions/number of samples as the augmented SDF 110. To perform an erosion or dilation operation, the shape transformer 118 can add the grid of bias values to the distance values of corresponding samples 115 of the augmented SDF 110, resulting in the modified SDF 120. In this example, if the bias value b is positive, the shape(s) 104 are eroded by b pixels. In contrast, if the bias value b is negative, the shape(s) 104 are dilated by b pixels. An example representation of dilation and erosion operations are described in connection with FIGS. 2A, 2B, and 2C.

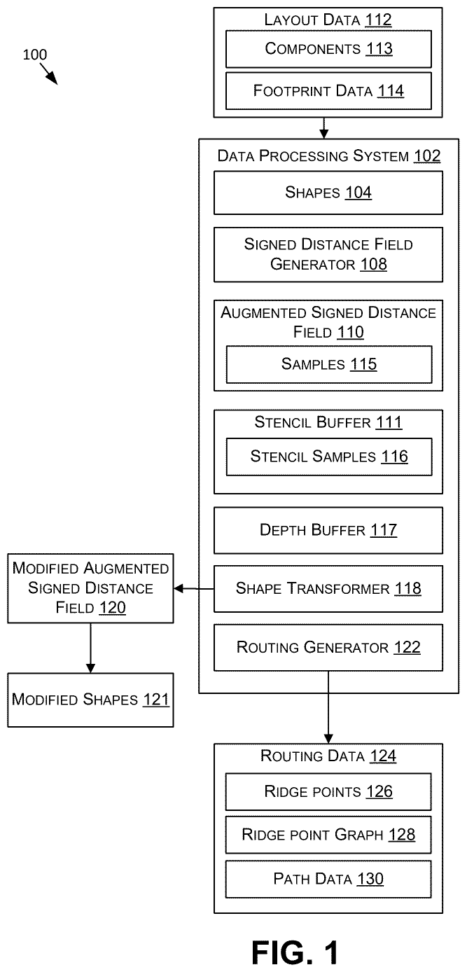

Referring to FIGS. 2A, 2B, and 2C in the context of the components described in connection with FIG. 1, depicted example diagrams 200A, 200B, and 200C showing resulting outputs of shape dilation and erosion techniques implemented using augmented signed distance fields, in accordance with some embodiments of the present disclosure. FIG. 2A illustrates an example augmented signed distance field 204 (e.g., an augmented signed distance field 110), with the region shaded with stripes indicating portions that are outside (e.g., having a positive distance value) of a first shape 206 and a second shape 208. Regions shaded with white are indicated as being positioned within (e.g., having a negative distance value) the first shape 206 and the second shape 208. The 0-isoline of the first shape 206 and the second shape 208 are indicated as a solid black line. Erosion and dilation operations applied to the example augmented signed distance field 204 are shown in FIGS. 2B and 2C.

FIG. 2B illustrates a diagram of an example erosion operation applied to the signed distance field 204 of FIG. 2A. As shown, the signed distance field 204 has been modified (e.g., resulting in a modified signed distance field 120) to produce an eroded shape 212. As shown, the region 210, which previously occupied by the entirety of the shape, has been reduced by adding a bias value b to each sample in the signed distance field 204. In this example, the region 214, which was previously occupied by the second shape 208 in FIG. 2A, has been completely eroded because all negative distance values indicating the interior of the shape have turned positive via addition of the bias value b.

FIG. 2C illustrates a diagram of an example dilation operation applied to the signed distance field 204 of FIG. 2A. As shown, the signed distance field 204 has been modified (e.g., resulting in a modified signed distance field 120) to produce a first dilated shape 218 and a second dilated shape 222. As shown, each of the first and second dilated shapes 218 and 222 appear as a uniformly expanded versions of the original shapes 206 and 208 of FIG. 2A, which are represented here as the regions 216 and 220. In this example, a bias value b has been added to the distance value of each sample in the augmented signed distance field, resulting in the appearance of the edges of each of the first and second dilated shapes 218 and 222.

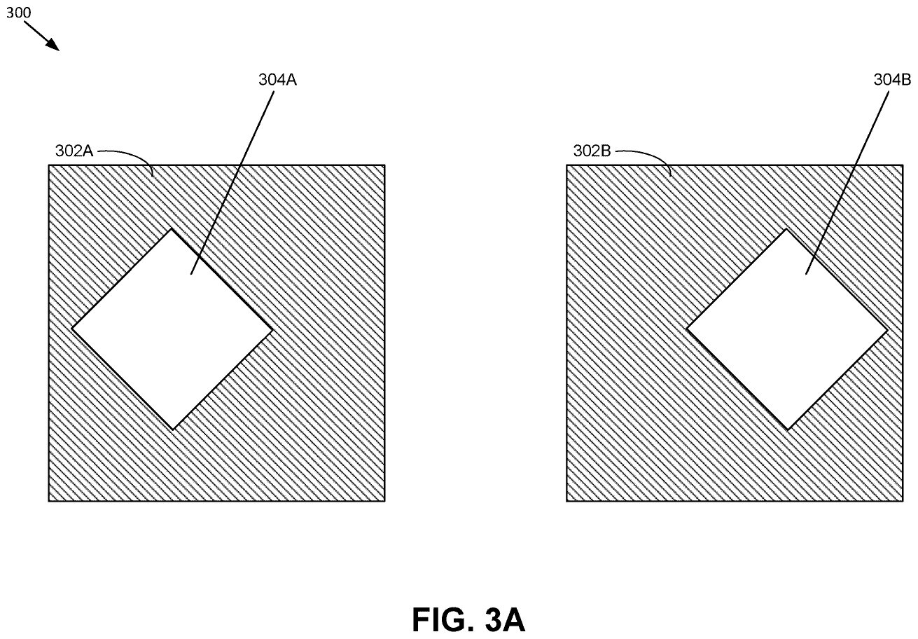

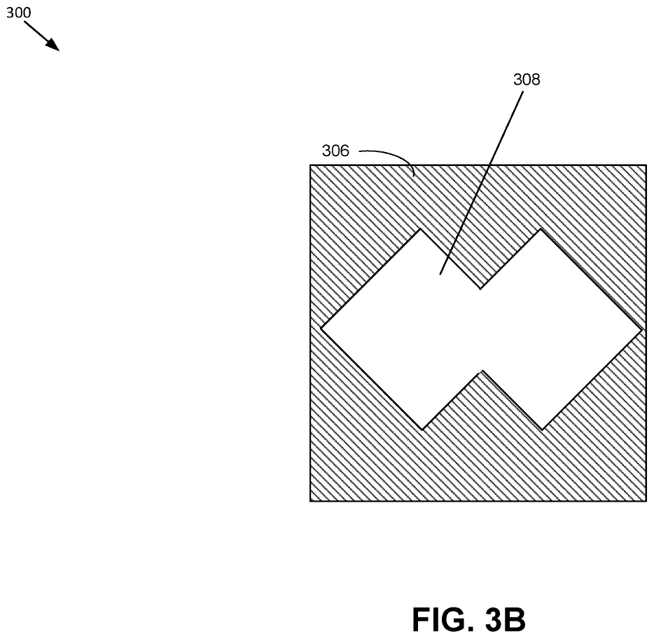

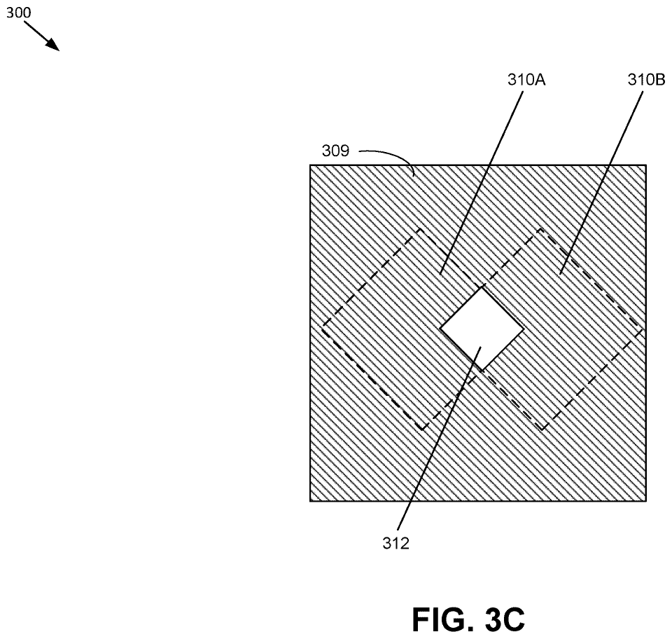

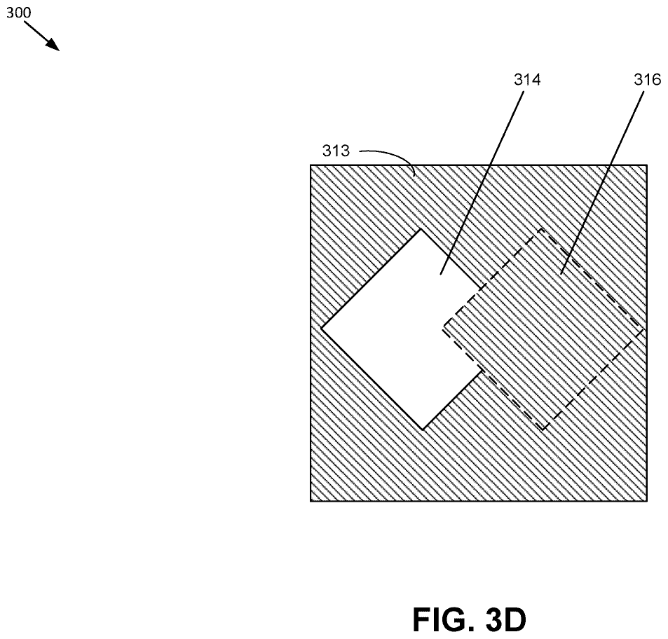

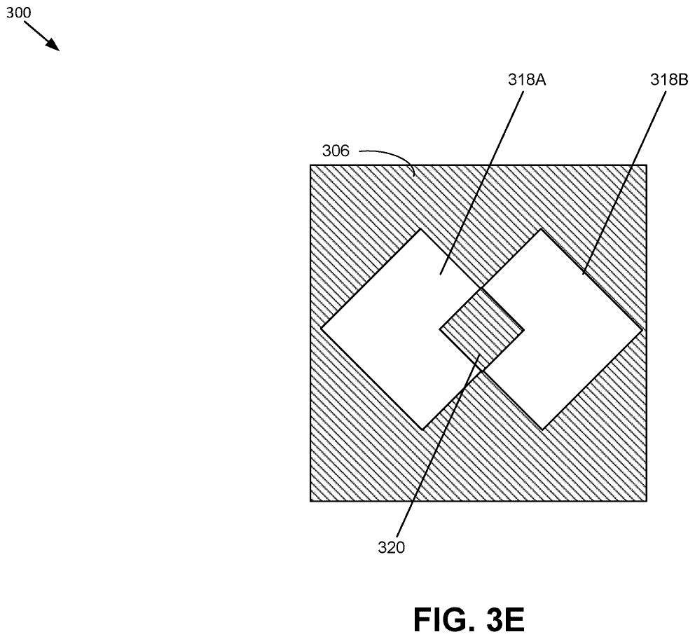

Referring back to FIG. 1, in some implementations, the shape transformer 118 may implement other types of operations involving multiple augmented signed distance fields 110 and/or sets of shapes 104. For example, in some implementations, the shape transformer 118 can perform Boolean operations, such as union, intersection, subtraction, or XOR operations, each of which are shown in connection with FIGS. 3B-3E. In such implementations, the shape transformer 118 can generate a modified augmented SDF 120 that is a combination of two or more augmented SDFs 110. The Boolean operations implemented by the shape transformer 118 can be pointwise/element-wise functions, enabling the operation to be carried out in parallel by the processing elements of one or more GPUs. Boolean operations can be performed on augmented SDFs 110 (or portions thereof) having the same size/dimensions, such that the modified augmented SDF 120 is a result of an operation applied to two or more corresponding samples 115 of the input augmented SDFs 110.

Example combination operations include a union operation, in which the shape transformer 118 applies an elementwise “min” operation to the distance values of each corresponding two samples 115 of input augmented SDFs 110. The gradient and tag value (if any) can be selected for inclusion in the corresponding output sample of the modified augmented SDF 120 from the sample 115 having the least distance value. To implement an intersection operation, the shape transformer 118 applies an elementwise “max” operation to the distance values of each corresponding two samples 115 of input augmented SDFs 110. The gradient and tag value (if any) can be selected for inclusion in the corresponding output sample of the modified augmented SDF 120 from the sample 115 having the greatest distance value.

Similar approaches can be used to implement a subtraction operation. A subtraction operation can be by first negating the distance values and gradient values of the subtrahend augmented SDF 110, and subsequently performing a max operation (as in the intersection case) between a first augmented SDF 110 and the negated subtrahend SDF 110. In this example, the gradient and tag value (if any) can be selected for inclusion in the corresponding output sample of the modified augmented SDF 120 from the sample 115 having the greatest distance value. Examples of these operations are described in connection with FIGS. 3A, 3B, 3C, 3D, and 3E.

Referring to FIGS. 3A, 3B, 3C, 3D, and 3E, depicted are example diagrams 300A, 300B, 300C, 300D, and 300E showing outputs of shape Boolean operations implemented using augmented signed distance fields, in accordance with some embodiments of the present disclosure. In the diagram 300A of FIG. 3A, two example augmented signed distance fields 302A and 302B (e.g., augmented SDFs 110) are shown, which include representations of shapes 304A and 304B (e.g., shapes 104), respectively. FIGS. 3B, 3C, 3D, and 3E show example combination operations performed using each of the augmented signed distance fields 302A and 302B.

The diagram 300B of FIG. 3B depicts an example union operation. As shown, the shapes 304A and 304B are combined such that the minimum distance value of each SDF sample is chosen for the modified augmented SDF 306 (e.g., a modified augmented SDF 120). This results in a single unified shape 308. The diagram 300C of FIG. 3C depicts an example intersection operation. As shown, the shapes 304A and 304B are combined such that the maximum distance value of each SDF sample is chosen for the modified augmented SDF 309 (e.g., a modified augmented SDF 120). This results in a single shape 312 that represents the intersection (e.g., overlap) between the shapes 304A and 304B. Note that in this operation, the regions 310A and 310B of the shapes 304A and 304B that do not overlap one another are now set to positive distance values, indicating that the samples within the regions 310A and 310B are located outside a boundary of the shape 312.

The diagram 300D of FIG. 3D depicts an example subtraction operation, in which the augmented SDF 302B of FIG. 3A is subtracted from the augmented SDF 302A of FIG. 3A. As described herein, the subtraction operation can involve negating the distance values of the subtrahend (e.g., the second augmented SDF 302B) and performing a “max” between the first augmented SDF 302A and the negated augmented SDF 302B. This results in maximum distance value of each SDF sample is chosen for the modified augmented SDF 313 (e.g., a modified augmented SDF 120). This results in a single shape 314, which represents all of the shape 304A without the region overlapped by the second shape 304B. Note that in this operation, the SDF samples of the region 316 previously occupied by the shape 304B are now set to positive distance values, indicating that the samples within the region 316 are located outside a boundary of the shape 314.

The diagram 300e of FIG. 3E depicts an example XOR operation. The XOR operation can be performed by first determining the union (e.g., as shown in FIG. 3B) between the augmented SDFs 302A and 302B of FIG. 3A and subtracting the intersection (e.g., as shown in FIG. 3C) between augmented SDFs 302A and 302B of FIG. 3A. As shown, this results in two modified shapes 318A and 318B, which are the same as a combination of the shapes 304A and 304B minus the overlapping region 320. In this operation, the SDF samples of the region 320 previously occupied by both of the shapes 304A and 304B are now set to positive distance values, indicating that the samples within the region 320 are located outside the boundaries of the shapes 318A and 318B.

Referring back to FIG. 1, the shape transformer 118 can perform any number or combination of dilation, erosion, or Boolean operations to generate useful output. In some implementations, the shape transformer 118 can perform specified transformation operations for any number of specified augmented SDFs 110 (or portions thereof) in response to requests from external computing systems, in response to operator input at the data processing system 102, or in response to messages from other processes (e.g., via inter-process communication) of the data processing system 102, among any other processing condition. In some implementations, the data processing system 102 can provide the modified augmented SDF 120 to the source of the request. In some implementations, the data processing system 102 may convert the modified augmented SDF 120 into one or more output shapes using the techniques described herein.

In some implementations, the shape transformer 118 can perform in-place signed distance field unions. Using the above techniques, the signed distance field combination operations can include the generation of N signed distance fields (and, with the example implementation, the allocation of N color textures) for N input filled paths C₁, C₂, . . . , C_{N}. To circumvent this allocation and generation steps, the shape transformer 118 can generate a modified augmented SDF 120 “in-place” for a union operation of N filled paths C, using a color texture, single depth buffer 117, and single stencil buffer, all of the same size.

To do so, the shape transformer 118 can perform similar operations to generate an augmented signed distance field 110, except that while generating the absolute signed distance values (e.g., prior to performing the stencil operations to negate values within shapes 104), the shape transformer 118 can generated absolute distance values clamped to [0, B₊] by operating over all links of all paths C₁, C₂, . . . , C_{N}, rather than just a single path C, as described herein. When performing the stencil operations to negate interior samples 115, the shape transformer 118 can clear the depth and stencil buffers to +1 and 0 respectively while retaining the color texture contents of the absolute distance field.

The shape transformer 118 can then execute the stencil operation for C described herein to set the depth value of all samples passed to “1,” while configuring the stencil test for all following steps to pass samples only when the stencil buffer has nonzero winding bits. The depth test operation can then be configured by the shape transformer 118 to accept incoming samples with lower depth than the resident sample. The distance stroking operation can be applied for each link L of C, modified so that no color texture modifications are performed, using the parameter values r=B+, v_{c}=0, vₛ=B₋, z_{c}=0.5, and zₛ=1. The depth test can then be configured (e.g., using corresponding API calls and/or driver function calls) by the shape transformer 118 to accept incoming samples with equal depth to the resident sample.

The distance stroking operation can then be applied for each link L of C, with same input values as above, except that color samples are conditionally passed when the income color sample encodes an SDF sample with an SDF value less-than-or-equal to the SDF value encoded by the resident color sample. The winding number bits of the stencil samples passed are set to zero. The shape transformer 118 can then configure the depth test to conditionally pass samples, and can apply the cover operation on C, setting the color samples passed to encode an SDF value of B₋, a zero SDF gradient, and placeholder (e.g., sentinel) tag value, while passing color samples conditionally with the same criterion described in the previous step. The depth value of all samples passed is set to “1”. By implementing this approach, the state of the stencil buffer 111 at the start and end of this process are identical.

Similar approaches can be implemented by the shape transformer 118 to perform in-place signed distance field bias operations, whose value is as if the shape transformer 118 had generated augmented SDFs 110 had been generated for filled paths C₁, C₂, . . . ,C_{N}, biased each of the augmented SDFs 110 using bias factors b₁, b₂, . . . , b_{N}, and combined them by performing a union operation. To do so, the shape transformer 118 can perform the same operations as the in-place union operation, while replacing the following parameters used to generate the absolute distance field: r=B₊−bᵢ, v_{c}=bᵢ, vₛ=B+, z_{c}=0.5+bᵢ/(2B₊), and zₛ=1, and using the following parameters when performing the distance stroking operation when changing the signs of distance values for interior samples: r=−B₋+bᵢ, v_{c}=bᵢ, vₛ=B₋, z_{c}=0.5-bᵢ/(2B₊), and zₛ=1. When performing this operation, the shape transformer 118 can clamp generated depth values to [0,1], and clamp the SDF distance values and gradients to [B₋, B₊] and 0, respectively, to maintain the affine transformation between depth and SDF value.

In some implementations, the shape transformer 118 can implement alternative distance values for interior samples 115 of augmented SDFs 110 to implement stroked paths. In the following example implementation, the stroked paths are described as having a circular cap style and a circular join style. Given a stroked path C and a stroked radius s, the interior of a path stroked is a set of points p such that the minimum distance between p and C is less than s. In implementing these techniques, the previous approach to generating augmented SDFs 110 is modified to process a sequence of paths C₁, C₂, . . . ,CN that include either stroked or filled paths, a corresponding sequence of bias factors b₁, b₂, . . . ,b_{N}, and a corresponding sequence of stroke radii s₁, s₂, . . . ,SN. When processing filled paths, the aforementioned algorithms are unchanged. When generating absolute distance values using distance stroke operations for stroked paths, the following parameters are used: r=B₊−bᵢ+sᵢ, v_{c}=bᵢ−sᵢ, vₛ=B+, z_{c}=0.5+ (bᵢ−sᵢ)/(2B₊), and zₛ =1, while the operations to negate the sign of interior samples 115 of stroked paths are skipped. When performing this operation, the shape transformer 118 can clamp generated depth values to [0,1], and clamp the SDF distance values and gradients to [B₋, B₊] and 0, respectively, to maintain the affine transformation between depth and SDF value.

Once the modified augmented SDF 120 is generated, the shape transformer 118 can extract the n-isoline of the modified augmented SDF 120 to generate one or more modified shapes 121 (e.g., in vector format, etc.). Extracting the n-isoline may be implemented to extract the modified shapes 121 resulting from the transformation operations performed by the shape transformer 118. To extract the modified shapes 121 from the modified augmented SDF 120, the shape transformer 118 can implement a marching squares algorithm. For the following explanation, the modified augmented SDF 120 can be represented by Fₛ, the gradient samples of the SDF Fₛ can be represented as Fₛ(x, y), with x and y being integer-plus-half values ranging in [0.5, w−0.5] and [0.5, h−0.5] respectively.

To perform the marching squares algorithm, the shape transformer 118 can allocate a gride of cells G represented here as G={G_{xy}|x:integer ∈[0, w], y:integer ∈[0, h]}, with each cell G_{xy} including the square of four input samples Fₛ(x−0.5, y−0.5), Fₛ(x+0.5, y−0.5), Fₛ(x−0.5, y+0.5), and Fₛ(x+0.5, y+0.5). The shape transformer 118 can initialize an atomic counter to zer0, and allocate a buffer of “micro edges,” which are ordered pairs of 2D points (e.g., a “start point” and an “end point”). For each cell, the shape transformer 118 can allocate/define two initially-empty point lists P_{entry}, Pₑₓᵢₜ, and define the “cell crossing analysis” function A (p₀, z₀, p₁, z₁, f), which takes a pair of points p0 and p₁, two corresponding distance values z₀ and z₁ of corresponding SDF samples 115 of the modified augmented SDF 120, and a Boolean “sidedness” value f. The cell crossing analysis function A can operates as:
if z₀≥ n and z₁≥n, no effect; otherwise,
if z₀≥n and z₁≤n, no effect; otherwise,
Define α=(n−z₀)/(z₁−z₀), and define the point p=p₀(1-σ)+p₁a
if (z₀<z₁)⊕f, add p to P_{entry}; otherwise add p to Pₑₓᵢₜ.

For each cell G_{xy}, the shape transformer 118 can execute the function A four times:

$$A ( ( x - 0 \text{.5} , y - 0.5 ) , {F}_{s} ( x - 0 \text{.5} , y - 0.5 ) , ( x - 0 \text{.5} , y + 0.5 ) , {F}_{s} ( x - 0 \text{.5} , y - 0.5 ) , true ) . \qquad 1$$

$$A ( ( x - 0 \text{.5} , y - 0.5 ) , {F}_{s} ( x - 0 \text{.5} , y - 0.5 ) , ( x + 0 \text{.5} , y + 0.5 ) , {F}_{s} ( x + 0 \text{.5} , y - 0.5 ) , false ) . \qquad 2$$

$$A ( ( x + 0 \text{.5} , y - 0.5 ) , {F}_{s} ( x + 0 \text{.5} , y - 0.5 ) , ( x + 0 \text{.5} , y + 0.5 ) , {F}_{s} ( x + 0 \text{.5} , y - 0.5 ) , false ) . \qquad 3$$

$$A ( ( x - 0 \text{.5} , y + 0.5 ) , {F}_{s} ( x - 0 \text{.5} , y + 0.5 ) , ( x + 0 \text{.5} , y + 0.5 ) , {F}_{s} ( x + 0 \text{.5} , y - 0.5 ) , true ) . \qquad 4$$

With respect to the operations above, operation (1) corresponds to calculations to the west, operation (2) corresponds to calculations to the south, operation (3) corresponds to calculations to the east, and operation (4) corresponds to calculations to the north.

These calculations result in Pentry and Pₑₓᵢₜ being of equal size E: either 0, 1, or 2 points each. The shape transformer 118 can assemble E micro edges by generating ordered pairs including one point of Pentry and one point of Pₑₓᵢₜ with each point used exactly once. If E>1, the generation of micro edges can be decided according to a domain-specific “saddle point disambiguation” approach. If E≠0, the shape transformer 118 can atomically add E to the atomic counter and writ ethe micro edges to the sub-section [E₀:E₀+E−1] of the output array, with E₀ being the value of the atomic counter prior to the increment. Micro edges generated according to these techniques can then be aggregated into the modified shapes 121, as described in further detail herein.

In some implementations, the shape transformer 118 can implement a gradient-enhanced variant of the marching squares algorithm. In such implementations, the shape transformer 118 can use the gradient samples embedded in the modified augmented SDF 120 to reduce artifacts in the process for reconstructing the modified shapes 121 from the modified augmented SDF 120. In doing so, the shape transformer 118 can define a “gradient cell crossing analysis” function Aₓ(p₀, p₁, f), which takes two points p₀ and p₁, and a “sidedness flag” f. The gradient cell crossing analysis can operate as:
1. Let zᵢ=Fₛ(pᵢ) and let

$${g}_{i} = \frac{\partial {F}_{s}}{\partial x} ( {p}_{i} )$$

(for i=0, 1),
2. Define two lines Lᵢ(t)=zᵢ+(t−i)gᵢ (e.g., extrapolate the partial gradients)
3. If L₀ and L₁ intersect at some t=t_{mid}, and t_{mid} ∈[0,1], then,
   a. Let z_{mid} be L₀ (tmid), (e.g., the extrapolated SDF distance value at the intersection point
   b. Let p_{mid}=(1−t_{mid})p₀+t_{mid}p₁
   c. Execute A (p₀, t₀, p_{mid}, t_{mid}, f)
   d. Execute A (p_{mid}, t_{mid}, p₁, t₁, f)
4. Otherwise, use a fallback approach such as the function A (p₀, z₀, p₁, z₁, f).
   The shape transformer 118 can implement a similar function Ay (p₀, p₁, f) which operates identically to Aₓ(p₀, p₁, f), except with y replacing the role of x.

To implement the gradient-enhanced marching squares algorithm, the shape transformer 118 can implement similar approaches to those described in connection with the marching squares algorithm, but replacing the four instances of executing the original function A with:

$${A}_{y} ( ( x - 0 \text{.5} , y - 0.5 ) , ( x - 0 \text{.5} , y + 0 \text{.5} ) , true ) . \qquad 1$$

$${A}_{x} ( ( x - 0 \text{.5} , y - 0.5 ) , ( x + 0 \text{.5} , y + 0.5 ) , false ) . \qquad 2$$

$${A}_{y} ( ( x + 0 \text{.5} , y - 0.5 ) , ( x + 0 \text{.5} , y + 0.5 ) , false ) . \qquad 3$$

$${A}_{x} ( ( x - 0 \text{.5} , y + 0.5 ) , ( x + 0 \text{.5} , y + 0.5 ) , true ) . \qquad 4$$

With respect to the operations above, operation (1) corresponds to calculations to the west, operation (2) corresponds to calculations to the south, operation (3) corresponds to calculations to the east, and operation (4) corresponds to calculations to the north.

The approaches described above can yield two point lists Pentry and Pₑₓᵢₜ being of equal size E, except that E ranges from 0 to 4, and therefore up to 4 micro edges are generated per cell G_{xy}, rather than 2. Micro edges generated according to the above techniques can be aggregated into the modified shapes 121, as described in further detail herein. The use of additional gradient information can reduce instances of artifacts and/or lost information when converting sub-pixel SDF data back into vector-based modified shapes 121, improving the accuracy of the aforementioned techniques. In some implementations, when executing the marching squares-based algorithms above, the shape transformer 118 can perform calculations association with each grid point G_{xy} using a respective processor of one or more GPUs, for example, by executing one or more corresponding API calls and/or driver functions of the one or more GPUs.

To aggregate generated micro edges into the modified shapes 121, the shape transformer 118 can connect the micro edges into closed contours, which is possible given the “closed contour property” of each point p, where the number of micro edges with p as its start point equals the number of micro edges with p as its end point. For the following example, let Sn and En denote the 2D start point and end point, respectively, for the n^{th} micro edge of the array of generated micro edges. A follow operation can be defined as:

$$follow ( x ) = y ⇔ {E}_{x} = {S}_{y}$$

The closed contour property of the marching squares algorithm ensures that such a “y” exists, however, this definition is ambiguous when multiple edges share Ex as a starting point. The follow operation used in these techniques can be a bijective function.

To aggregate the micro edges, the shape transformer 118 can sort the micro edges into equivalence classes of contours, where x=y iff x=followⁿ(y) for some n. shape transformer 118 can determine the number of edges in each contour. This can be considered the “period” of each contour, for example, the minimal positive n such that x=followⁿ(x) for some edge x in the contour. The shape transformer 118 can extract the list of points for each contour. As the contours can be closed, there may not necessarily be a start or end point for each contour. However, this approach can ensure the arbitrary choice of which point is first in the array is deterministic despite potentially the unpredictable order of the input micro edges in the micro edge array.

To aggregate the micro edges in this manner, the shape transformer 118 can first construct an array jump¹[x] such that jump¹[x]=follow (x). The shape transformer 118 can then construct arrays jump^{N}[x]=follow^{N}(x), for N=2,4,8, . . . , up until the highest power of two strictly less than the total number of micro edges. This may be performed by setting jump^{2N}[x]=jump^{N}[jump^{N}[x]] for each micro edge x. The shape transformer 118 can then determine equivalence classes of the micro edges. For each equivalence class, the shape transformer 118 can select a representative edge x with the minimal value for Sₓ. This can include creating output arrays “follow_count” and “representative_index”, such that representative_index [x] is the index of the representative for the equivalence class that x is in, and follow_count [x] is the minimal integer N such that followⁿ(x) is said representative edge. Note that it is possible that N=0. Further details of this equivalence class algorithm are described herein.

The shape transformer 118 can then allocate an array of points, and suballocate within that array sections sized for each contour equivalence class. The shape transformer 118 can allocate an auxiliary array “representative_to_idx” such that representative_to_idx [x] gives the location of the subarray allocated for the contour with representative x. For each edge n, the shape transformer 118 can:
1. Identify its representative edge x in representative_index
   2. Identify the location of the subarray corresponding to this equivalence class in representative_to_idx. Let L be the size of this subarray (or, identically, the equivalence class for n)
3. Write En to index L−1− follow_count[n] of the subarray. Note that Sy need not necessarily be written, as it is implicitly the previous point in the subarray (wrapping around)
   Also note that follow_count[n] will be zero if edge n is the representative of its own equivalence class. The last point of the subarray of each contour can always be the end point of its representative edge. This determinism of the choice of n (e.g., minimal Sn)provides the desired determinism.

The shape transformer 118 can execute an equivalence class algorithm, which may be used in executing the aforementioned calculations, to assign a unique “minimal” micro edge for each equivalence class and maps each micro edge to said representative of its equivalence class. At the start of the equivalence class algorithm, the shape transformer 118 can, for each edge n, initialize representative_index[n]=n and follow_count[n]=0. For each jump table jump in jump¹, jump², jump⁴jump⁸, . . . until the last jump table, then for each edge n, the shape transformer 118 can:
1. Let x=representative_index[n] and y=representative_index [jump^{J}[n]]
2. Let p=Sₓ≤S_{y}. This can include defining a strict ordering for the 2D points, so that the “minimal” definition is consistent, which may be implemented, for example, with a comparison of the points binary representations.
3. Set representative_index[n]=p?x:y
4. Set follow_count[n]=p? follow_count[n]: follow_count [jump^{J}[n]]+J
   The input and outputs can be double buffered in the one or more GPUs, in some implementations.

Note that prior to the step for jump^{J},
1. x=representative_index[n] is the member of {x|x=follow^{F}(n) for some 0≤F<]} of minimal Sₓ.
2. follow_count[n] is the minimal F such that x=follow^{F}(n).
   After said step, the same is true, with 0≤F<J replaced with 0≤F<2J. As the last J is the highest power of 2 strictly under the edge count, 2J is at least the edge count. This bounds the maximum period of each contour, so, after the last step, representative_index[n] is indeed the index of the representative edge of the equivalence class including edge n. Upon executing these algorithms, the shape transformer 118 can access the subarray of each contour to generate the modified shapes 121, with each contour corresponding to a respective modified shape 121.

The data processing system 102 can provide the modified shapes 121 and/or the modified augmented SDF(s) 120 as output data. The output data may be provided, for example, to one or more CAD processes and/or provided for display via one or more output devices (e.g., display devices) of the data processing system 102. In some implementations, the data processing system 102 can receive layout data 112 from and provide corresponding output data to one or more client devices. In such implementations, the data processing system 102 can receive the layout data 112 and identifications of one or more transformation operation(s) to perform via a network, process the shapes 104 of the layout data 112 to perform the specified transformation operation(s), and provide the output data via the network in response to receiving the layout data 112.

In addition to executing the shape transformer 118 to perform transformation operations, the data processing system 102 can execute the routing generator 122 to perform automatic routing operations using the augmented SDF 110 generated using the SDF generator 108, as described herein. The routing generator 122 can include hardware, software, or combinations of hardware and software. The routing generator 122 can be executed by the data processing system 102 in response to a request from one or more external computing systems, in response to operator input at the data processing system 102, and/or in response to one or more signals from other processes/functions executed by the data processing system 102 (e.g., received via inter-process communication, etc.).

The routing generator 122 can be used to generate output routing data 124, which can include indications of path data 130 between nodes of a ridge point graph 128. To do so, the routing generator 122 can use the gradient values of the samples 115 of an augmented SDF 110 to identify spaces between one or more shapes 104. These spaces can be identified based on discontinuities in the gradients of the augmented SDF 110. When a discontinuity is identified, the routing generator 122 can generate a ridge point 126 identifying the location of the discontinuity and can assemble a network of ridge points 126 into a ridge point graph 128. As the points and edges in the ridge point graph are constructed to occupy spaces between shapes 104 in the augmented SDF 110, routing algorithms can be executed to identify a viable path 130 through the ridge point graph 128 between components/locations.

The routing generator 122 can identify one or more ridge points 126 based on the gradient values of the samples 115 of an augmented SDF 110 generated from one or more shapes 104. For the following analysis, the gradient values of the samples 115 of an augmented SDF 110 used to identify/generate ridge points 126 can be considered integer-plus-half coordinates (x, y), with x and y ranging in [0.5, w−0.5] and [0.5, h−0.5] respectively. The routing generator 122 can generate/allocate (e.g., in memory of one or more GPUs) a set of cells G_{xy}, which can represent unit squares centered at (x, y) with x and y integers in [1, w−1] and [1, h−1] respectively. The four counters of the unit square can correspond to locations of the distance/SDF values and the gradient values of the samples 115, as the samples 115 can be considered to lie on integer-plus-half coordinate values.

The routing generator 122 can allocate a data structure, such as a texture data structure, which is to store the ridge points 126. This data structure may sometimes be referred to as a “ridge point texture,” and can include one Boolean samples at (x, y) for each cell G_{xy}. The routing generator 122 can then evaluate a Boolean gradient discontinuity heuristic for each cell G_{xy}. The gradient discontinuity heuristic can use the distance/SDF value and the gradient values of the samples 115 at the corners of the cell G_{xy}. If the gradient discontinuity heuristic is satisfied, the routing generator 122 can set the Boolean value of the corresponding ridge point texture to “1”. In some implementations, each cell G_{xy} can be evaluated using a respective processor of the one or more GPUs, enabling a high degree of parallelism.

The gradient discontinuity heuristic can be any set of conditions that can detect a discontinuity in set of gradient values of the augmented SDF 110. An example gradient discontinuity heuristic can use a divergence parameter q and a minimum SDF distance value parameter zₘᵢₙ. If the distance/SDF values of any of the samples 115 corresponding to a cell G_{xy} are less than zₘᵢₙ, the example gradient discontinuity heuristic returns false (e.g., is not satisfied). Otherwise, the gradient values of a pair of samples 115 is divergent if their dot product is less than the divergence parameter q. The routing generator 122 can evaluate the six pairwise dot products of the four corner SDF samples 115, and determine which pairs are divergent. The example gradient discontinuity heuristic is set to true (e.g., is satisfied) if at least three gradient pairs are divergent, and at least two of those pairs are horizontally or vertically adjacent. In some implementations, the color textures storing the samples 115 of the augmented SDF 110 and the ridge texture data can have texel coordinates (x, y) that correspond to SDF sample coordinates (x+0.5, y+0.5) and ridge point 126 coordinates (x+1, y+1), respectively.

Note that discontinuities detected in the augmented SDF 110 occur in regions at about the midpoint between shapes, and therefore can be used to identify routing paths that do not intersect with any of the shapes 104. Once the ridge points 126 are identified, the routing generator 122 can connect the ridge points 126 to generate a ridge point graph 128. Certain junction ridge points 126 can be represented as nodes in the ridge point graph 128. To generate a ridge point graph 128, the routing generator 122 can generate additional points that connect the generated ridge points 126 stored in the ridge point texture, thereby defining edges that connect the junction ridge points 126 as nodes in the ridge point graph 128.

To add additional points to generate the ridge point graph 128, the routing generator 122 can use an algorithm to iteratively connect a point p to the set of ridge points 126 (represented in the following example as R). The additional point p can be connected using the ridge point texture storing the ridge points 126 and the augmented SDF 110 from which the ridge points were identified/generated. The routing generator 122 can use this approach to iterative close “gaps” to form the ridge graph 128, by iteratively applying the connection algorithm to one or more points p selected from the ridge points R. Additionally, this approach can be used to connect an initial start point p to the ridge graph 128, for example, to route a point from a component terminal or trace (which can intersect with a shape 104) to other points in the ridge graph 128.

For the following example connection algorithm, the same definition of cells G_{xy} is used, as described herein, with the same w and h notation for the bounds of the samples 115 of the input augmented SDF 110. At the start of the process, the point p (which may be one of the ridge points 126, or any other selected point) can be rounded to the nearest integer-value coordinates, represented as v. The routing generator 122 can then, iteratively:
1. Determine whether v exceeds the bounds [1, w−1] x [1, h−1], and if so, terminate.
2. Otherwise, identify/sample the gradient value g of the nearest SDF sample 115 to v.
3. Define G_{xy} as the cell that includes v, and if there are multiple possible choices, round in the direction of the gradient g (e.g., prefer the cell G_{xy} with the highest dot product (x, y) g.
4. If (x, y) E R, rasterize a line from v to (x, y) into the ridge texture, with samples covered by the line modified to encode true values, then terminate. This can define new ridge points along the path of the line. In some implementations, this step may ignore (x, y) that match the initial position of p.
5. Otherwise, define a line A(t)=v+gₜ.
6. Clip the line A to the bounds of the unique square cell G_{xy} and denote the endpoints of the line as A(t₀) and A(t₁).
7. Assuming t₁≥ to, set v to A(t₁). If the value of v did not change, then terminate. Otherwise, loop back to step 1.

The connections formed between ridge points can be defined as edges in the ridge point graph 128. In some implementations, the routing generator 122 can store edges as part of the ridge point graph 128 as defined by an adjacency function A (r₀, r₁) that defines whether two ridge points are connected by an edge. When performing routing, for each routing start or end point p, the routing generator 122 can search for a ridge point 126 r₀ to connect to p by following the gradient values of the SDF samples 115 using the above-described algorithm.

In some implementations, the routing generator 122 can identify “gap points” in the ridge graph by identifying unexpected end points in the graph. These gap points can be input as respective points p in the above-described algorithm to form connections to existing ridge points 126 in the ridge point graph 128. In some implementations, the routing generator 122 can perform a graph simplification process, in which vertices v₁ of degree 2 are removed from the ridge point graph 128 that are not needed for performing routing processes. Two edges connecting to 11, represented as (v₀, v₁) and (v₁, v₂) can be simplified to a single merged edge (v₀, v₂). Simplification can be performed prior to or subsequent to identifying the start and end points for a given routing process.

The routing generator 122 can identify start and end points for a routing process to generate path data 130 through the ridge graph 128. In some implementations, the ridge graph 128 can be stored as a set of nodes (e.g., with each node having spatial coordinates of a respective ridge point 126) connected by edges. The edges can be defined along discontinuities in the gradient data of the augmented SDF 110. The start and end points for the routing process can be identified from a request, which may be received from an external computing system in communication with the data processing system 102, via operator input to the data processing system 102, or from one or more other processes or functions executed by the data processing system 102. In one example, routing between points can be determined in response to an interaction with CAD software for circuit layouts. The interaction(s) may specify the start and end points between which the routing is to occur.

Once the start/end points have been identified, the routing generator 122 can determine whether the start/end points are included in the ridge point graph 128 as nodes. If the start/end points are not included in the ridge point graph 128 as nodes, the routing generator 122 can execute the algorithm described herein above, using each of the start/end points as an input point p, to add the start/end points to the ridge point graph 128. Once added to the ridge point graph 128, the ridge point graph 128 can execute a routing algorithm to determine a path through the ridge point graph 128 starting at the start point node and ending at the end point node. The path determined using the routing algorithm can be stored as the path data 130 of the routing data 124. Any suitable routing algorithm can be used, including but not limited but limited to Dijkstra's algorithm, the A*algorithm, the Bellman-Ford algorithm, a breadth-first search-based algorithm, or a depth-first search-based algorithm, among others. In some implementations, the path data 130 can be stored as an ordered sequence of points, which when connected form the path through the ridge point graph 128.

The data processing system 102 can provide the routing data 124 and/or the path data 130 as output data. The output data may be provided, for example, to one or more CAD processes and/or provided for display via one or more output devices (e.g., display devices) of the data processing system 102. In some implementations, the data processing system 102 can receive start/end points and/or layout data 112 from and provide corresponding output data to one or more client devices. In such implementations, the data processing system 102 can receive the layout data 112 via a network, process the shapes 104 of the layout data 112 to perform transformation operation(s).

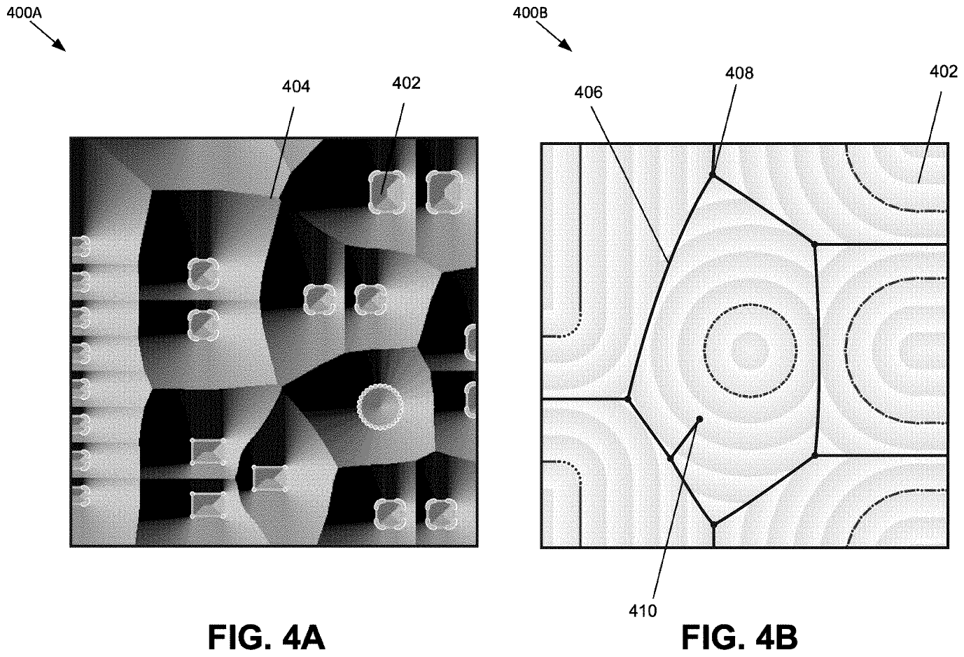

Referring to FIGS. 4A and 4B, depicted are example diagrams showing how gradients of augmented signed distance fields are used to generate a ridge graph (e.g., a ridge point graph 128) for circuit routing, in accordance with some embodiments of the present disclosure. FIG. 4A shows a diagram 400A of an augmented SDF, with sample gradient values represented as respective pixel colors. In the example augmented SDF of diagram 400A, the x and y gradient values of each sample is represented as a respective color channel in each pixel. As such, gradual changes in color correspond to gradual changes in the gradient, while rapid changes in color correspond to large changes in the gradient. As described herein, the gradient can indicate the direction away from the closest shape 402. At about the midpoint between any two shapes 402, a discontinuity 404 appears, in which the gradient direction suddenly changes, reflecting that the corresponding SDF samples are closer to a different shape. These gradient discontinuities 404 can be detected using the techniques described herein, and used to generate a ridge graph (e.g., a ridge point graph 128). As the discontinuities are generally at the midpoint between any two shapes 402, any path routed along these discontinuities will avoid intersection with any of the shapes 402. An example representation of a ridge point graph is shown in FIG. 4B.

Referring to FIG. 4B, depicted is an example diagram 400B an example ridge point graph (e.g., a ridge point graph 128) superimposed over an example augmented SDF (e.g., an augmented SDF 110). As described herein, the ridge point graph is defined along the discontinuities between shapes 402. The ridge point graph can include a number of nodes 408 connected by edges 406. The nodes 408 can include ridge points. The edges can be generated by connecting ridge points following the discontinuities indicated in the gradients of the augmented SDF, as described herein. In this example, an additional point 410 has been added, which is positioned close to a shape 402. The additional point 410 can automatically be included as a node in the ridge point graph and connected using an additional edge 408. In this example, the additional point 410 may correspond to a start point or an end point that may be used in routing through the ridge point graph. In one example, viable paths can be identified by traversing the nodes 408 and edges 406 of the ridge point graph to provide possible paths for routing traces for PCB layouts.

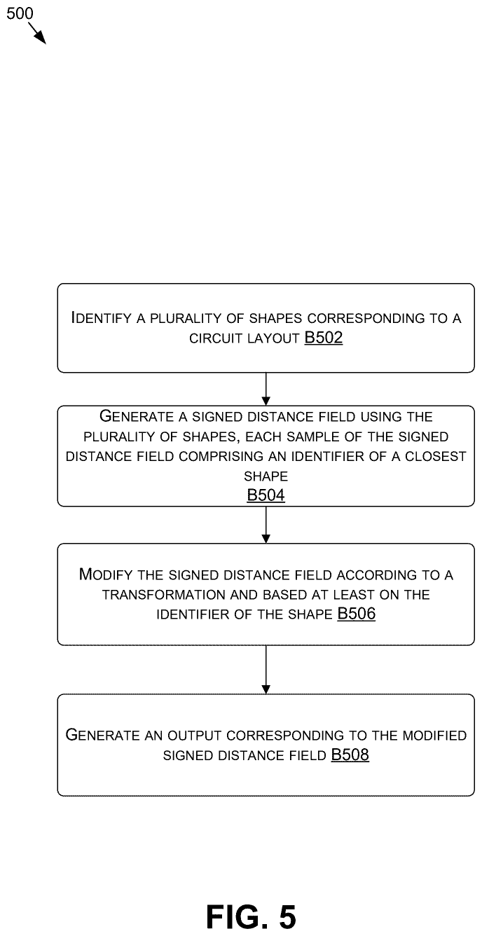

Now referring to FIG. 5, each block of method 500, described herein, includes a computing process that may be performed using any combination of hardware, firmware, and/or software. For instance, various functions may be carried out by one or more processors executing instructions stored in memory. The method may also be embodied as computer-usable instructions stored on computer storage media. The method may be provided by a standalone application, a service or hosted service (standalone or in combination with another hosted service), or a plug-in to another product, to name a few. In addition, method 500 is described, by way of example, with respect to the system of FIG. 1. However, this method may additionally or alternatively be executed by any one system, or any combination of systems, including, but not limited to, those described herein.

FIG. 5 is a flow diagram of an example method 500 for implementing shape transformation operations using augmented signed distance fields (e.g., augmented SDFs 110), in accordance with some embodiments of the present disclosure. The method 500, at block B502, includes identifying a plurality of shapes (e.g., shapes 104) corresponding to a circuit layout (e.g., layout data 112). In some implementations, the shapes can correspond to circuit elements, traces, or ground/power planes. The shapes may be extracted from the circuit layout data and can include vector information. For example, the shapes can be represented as piecewise continuous paths. In some implementations, the shapes may be provided by one or more external computing systems or from one or more processes (e.g., CAD software for manipulating circuit layouts, etc.). The shapes may be received in a request to perform one or more transformation operations.

The method 500, at block B504, includes generating a signed distance field (e.g., an augmented SDF 110) using the plurality of shapes. Each sample of the signed distance field can include an identifier of the closest shape of the plurality of shapes. The signed distance field may be an augmented signed distance field and can be generated as a texture having a plurality of pixels. The dimensions of the signed distance field can correspond to the circuit layout (or a subset thereof), such that all shapes identified in step 502 can be represented in the signed distance field. Each sample of the augmented SDF can be represented as a pixel in the texture. The signed distance value of each sample can be stored as a first color channel of each pixel (e.g., a red channel). A 2D gradient of each sample, stored as a 2D unit vector pointing away from the closest link of the closest shape for positive distance samples and pointing towards the closest link for negative distance samples, can be represented in two color channels (e.g., the green and blue channels) of each pixel. The identifier of the closest shape can be stored as a tag value in another channel of each pixel (e.g., an alpha channel). The tag value can, in some implementations, uniquely identify the closest segment of the closest shape. Generating the signed distance field can include performing any of the operations of the SDF generator 108 described in connection with FIG. 1.

The method 500, at block B506, includes modifying the signed distance field according to a transformation operation and based at least on the identifier of the closest proximate path. For example, the transformation operation may designate one or more shapes to transform (e.g., dilate, erode, etc.). The transformation operation may include erosion operations, dilation operations, or Boolean operations such as union, intersection, subtraction, or XOR operations, as described in connection with FIGS. 2A-3E. Modifying the signed distance field can include performing any of the operations described in connection with the shape transformer 118 of FIG. 1. Modifying the signed distance field can include generating a modified signed distance field (e.g., a modified augmented SDF 120). In some implementations, the transformation operation may include an “in-place” union and dilation/erosion operation, in which shapes from multiple circuits are used to perform a union operation and a subsequent dilation/erosion operation using a single augmented signed distance field.

The method 500, at block B508, includes generating output (e.g., modified shapes 121) corresponding to the modified signed distance field. For example, the modified signed distance field generated at block B508 can be used to generate a set of modified shapes. The modified shapes may be extracted by fitting curves to the modified signed distance field. In some implementations, this may include performing a marching squares algorithm or variant thereof to generate a set of mini edges from the modified signed distance field. Once generated, the mini edges can be combined into lines, curves, or other geometric features of the modified shapes (e.g., in a vector-based format). The modified shapes can be provided as output to the computing system or process that requested the transformation operation of the input shapes.

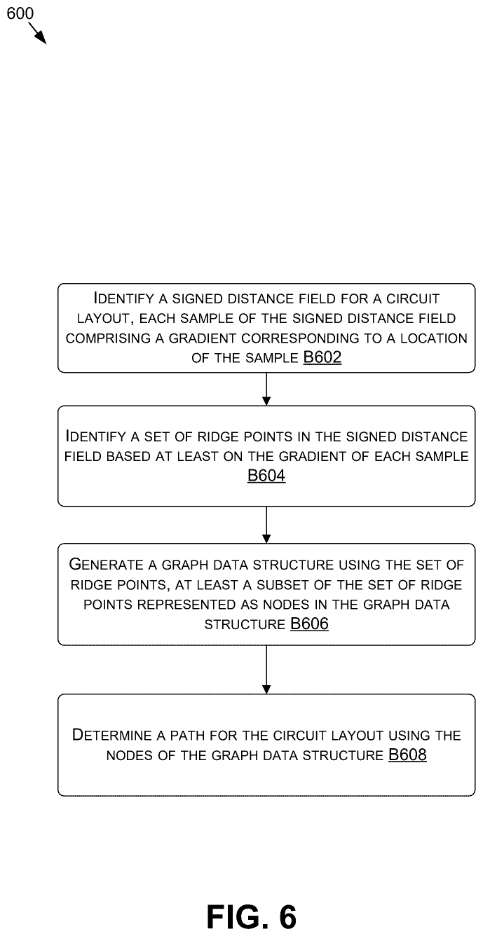

Now referring to FIG. 6, each block of method 600, described herein, includes a computing process that may be performed using any combination of hardware, firmware, and/or software. For instance, various functions may be carried out by one or more processors executing instructions stored in memory. The method may also be embodied as computer-usable instructions stored on computer storage media. The method may be provided by a standalone application, a service or hosted service (standalone or in combination with another hosted service), or a plug-in to another product, to name a few. In addition, method 600 is described, by way of example, with respect to the system of FIG. 1. However, this method may additionally or alternatively be executed by any one system, or any combination of systems, including, but not limited to, those described herein.

FIG. 6 is a flow diagram of an example method 600 for implementing routing operations using augmented signed distance fields (e.g., augmented SDFs 110), in accordance with some embodiments of the present disclosure. The method 600, at block B602, includes identifying a signed distance field (e.g., an augmented SDF 110) for a circuit layout (e.g., layout data 112). Each sample (e.g., samples 115) of the signed distance field can include a gradient of the signed distance field corresponding to a location of the sample. The circuit layout can have one or more shapes (e.g., shapes 104) corresponding to the footprints of components, traces, or power/ground planes. The signed distance field may be an augmented signed distance field and can be generated as a texture having a plurality of pixels. The dimensions of the signed distance field can correspond to the circuit layout (or a subset thereof), such that all shapes identified in step 502 can be represented in the signed distance field. The gradient of each sample, stored as a 2D unit vector pointing away from the closest link of the closest shape, can be represented in two color channels (e.g., the green and blue channels) of each pixel. The signed distance field can be generated by performing any of the operations of the SDF generator 108 described in connection with FIG. 1.

The method 600, at block B604, includes identifying a set of ridge points (e.g., ridge points 126) in the signed distance field based at least on the gradient of each sample of the signed distance field. For example, the gradients of the signed distance field can indicate one or more discontinuities. The discontinuities can be located in regions between shapes of the circuit layout and can occur when the gradient changes direction. In some implementations, the ridge points can be generated as a ridge point texture, with each pixel having a Boolean value indicating whether the location of the pixel includes a ridge point. Identifying the ridge points can include performing any of the operations of the routing generator 122 of FIG. 1.

The method 600, at block B606, includes generating a graph data structure (e.g., a ridge point graph 128) using the set of ridge points identified in step B604. The ridge point graph can be generated by generating connections between the ridge points. In some implementations, this can include rasterizing one or more lines between the initial ridge points in the ridge point texture generated in step B604. In some implementations, generating the graph data structure can include generating additional nodes/ridge points for inclusion in the graph data structure, which may correspond to start or end points for a routing process.

The method 600, at block B608, includes determining a path (e.g., path data 130) for the circuit layout using the nodes of the graph data structure. The path may an optimal (e.g., shortest)path between a start and an end point in the ridge point graph. The path can be generated using any suitable path finding algorithm, including Dijkstra's algorithm, A*-based algorithm, a breadth-first search-based algorithm, or a depth-first search-based algorithm, amongst others. In some implementations, the path may be generated to connect two shapes in the circuit layout (e.g., terminals of different components, etc.). Once generated, the path can be provided as output. In some implementations, the output may be provided to a computing system or process/function that requested generation of the path.

The systems and methods described herein may be used for a variety of purposes, by way of example and without limitation, for circuit layout definition, machine control, machine locomotion, machine driving, synthetic data generation, model training, perception, augmented reality, virtual reality, mixed reality, robotics, security and surveillance, simulation and digital twinning of objects, actors or environments, autonomous or semi-autonomous machine applications, deep learning, environment simulation, data center processing, conversational artificial intelligence (AI), light transport simulation (e.g., ray-tracing, path tracing, etc.), collaborative content creation for three-dimensional (3D) assets, cloud computing, generative AI, and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems implementing one or more language models-such as one or more large language models (LLMs), systems for performing light transport simulation, systems for performing collaborative content creation for 3D assets, systems implemented at least partially using cloud computing resources, and/or other types of systems.

### Example Computing Device

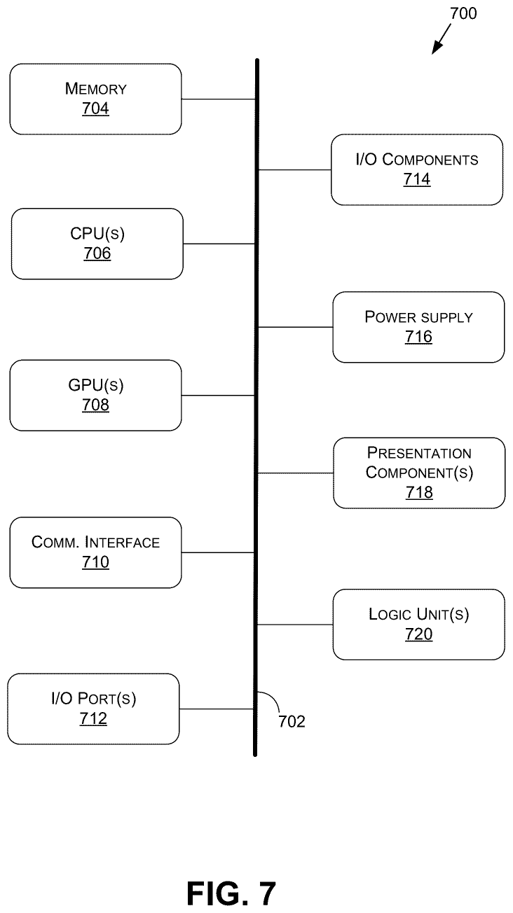

FIG. 7 is a block diagram of an example computing device(s) 700 suitable for use in implementing some embodiments of the present disclosure. Computing device 700 may include an interconnect system 702 that directly or indirectly couples the following devices: memory 704, one or more central processing units (CPUs) 706, one or more graphics processing units (GPUs) 708, a communication interface 710, input/output (I/O)ports 712, input/output components 714, a power supply 716, one or more presentation components 718 (e.g., display(s)), and one or more logic units 720. In at least one embodiment, the computing device(s) 700 may comprise one or more virtual machines (VMs), and/or any of the components thereof may comprise virtual components (e.g., virtual hardware components). For non-limiting examples, one or more of the GPUs 708 may comprise one or more vGPUs, one or more of the CPUs 706 may comprise one or more vCPUs, and/or one or more of the logic units 720 may comprise one or more virtual logic units. As such, a computing device(s) 700 may include discrete components (e.g., a full GPU dedicated to the computing device 700), virtual components (e.g., a portion of a GPU dedicated to the computing device 700), or a combination thereof.

Although the various blocks of FIG. 7 are shown as connected via the interconnect system 702 with lines, this is not intended to be limiting and is for clarity only. For example, in some embodiments, a presentation component 718, such as a display device, may be considered an I/O component 714 (e.g., if the display is a touch screen). As another example, the CPUs 706 and/or GPUs 708 may include memory (e.g., the memory 704 may be representative of a storage device in addition to the memory of the GPUs 708, the CPUs 706, and/or other components). In other words, the computing device of FIG. 7 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 7.

The interconnect system 702 may represent one or more links or busses, such as an address bus, a data bus, a control bus, or a combination thereof. The interconnect system 702 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 706 may be directly connected to the memory 704. Further, the CPU 706 may be directly connected to the GPU 708. Where there is direct, or point-to-point connection between components, the interconnect system 702 may include a PCIe link to carry out the connection. In these examples, a PCI bus need not be included in the computing device 700.

The memory 704 may include any of a variety of computer-readable media. The computer-readable media may be any available media that may be accessed by the computing device 700. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 704 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 700. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 706 may be configured to execute at least some of the computer-readable instructions to control one or more components of the computing device 700 to perform one or more of the methods and/or processes described herein. The CPU(s) 706 may each include one or more cores (e.g., one, two, four, eight, twenty-eight, seventy-two, etc.) that can handle a multitude of software threads simultaneously. The CPU(s) 706 may include any type of processor and may include different types of processors depending on the type of computing device 700 implemented (e.g., processors with fewer cores for mobile devices and processors with more cores for servers). For example, depending on the type of computing device 700, the processor may be an Advanced RISC Machines (ARM)processor implemented using Reduced Instruction Set Computing (RISC) or an x86 processor implemented using Complex Instruction Set Computing (CISC). The computing device 700 may include one or more CPUs 706 in addition to one or more microprocessors or supplementary co-processors, such as math co-processors.

In addition to or alternatively from the CPU(s) 706, the GPU(s) 708 may be configured to execute at least some of the computer-readable instructions to control one or more components of the computing device 700 to perform one or more of the methods and/or processes described herein. One or more of the GPU(s) 708 may be an integrated GPU (e.g., with one or more of the CPU(s) 706 and/or one or more of the GPU(s) 708 may be a discrete GPU. In embodiments, one or more of the GPU(s) 708 may be a coprocessor of one or more of the CPU(s) 706. The GPU(s) 708 may be used by the computing device 700 to render graphics (e.g., 3D graphics) or perform general purpose computations. For example, the GPU(s) 708 may be used for General-Purpose computing on GPUs (GPGPU). The GPU(s) 708 may include hundreds or thousands of cores that are capable of handling hundreds or thousands of software threads simultaneously. The GPU(s) 708 may generate pixel data for output images in response to rendering commands (e.g., rendering commands from the CPU(s) 706 received via a host interface). The GPU(s) 708 may include graphics memory, such as display memory, for storing pixel data or any other suitable data, such as GPGPU data. The display memory may be included as part of the memory 704. The GPU(s) 708 may include two or more GPUs operating in parallel (e.g., via a link). The link may directly connect the GPUs (e.g., using NVLINK) or may connect the GPUs through a switch (e.g., using NVSwitch). When combined together, each GPU 708 may generate pixel data or GPGPU data for different portions of an output or for different outputs (e.g., a first GPU for a first image and a second GPU for a second image). Each GPU may include its own memory or may share memory with other GPUs.

In addition to or alternatively from the CPU(s) 706 and/or the GPU(s) 708, the logic unit(s) 720 may be configured to execute at least some of the computer-readable instructions to control one or more components of the computing device 700 to perform one or more of the methods and/or processes described herein. In embodiments, the CPU(s) 706, the GPU(s) 708, and/or the logic unit(s) 720 may discretely or jointly perform any combination of the methods, processes and/or portions thereof. One or more of the logic units 720 may be part of and/or integrated in one or more of the CPU(s) 706 and/or the GPU(s) 708 and/or one or more of the logic units 720 may be discrete components or otherwise external to the CPU(s) 706 and/or the GPU(s) 708. In embodiments, one or more of the logic units 720 may be a coprocessor of one or more of the CPU(s) 706 and/or one or more of the GPU(s) 708.

Examples of the logic unit(s) 720 include one or more processing cores and/or components thereof, such as Data Processing Units (DPUs), Tensor Cores (TCs), Tensor Processing Units (TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 710 may include one or more receivers, transmitters, and/or transceivers that enable the computing device 700 to communicate with other computing devices via an electronic communication network, included wired and/or wireless communications. The communication interface 710 may include components and functionality to enable communication over any of a number of different networks, such as wireless networks (e.g., Wi-Fi, Z-Wave, Bluetooth, Bluetooth LE, zigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 720 and/or communication interface 710 may include one or more data processing units (DPUs) to transmit data received over a network and/or through interconnect system 702 directly to (e.g., a memory of) one or more GPU(s) 708.

The I/O ports 712 may enable the computing device 700 to be logically coupled to other devices including the I/O components 714, the presentation component(s) 718, and/or other components, some of which may be built in to (e.g., integrated in) the computing device 700. Illustrative I/O components 714 include a microphone, mouse, keyboard, joystick, game pad, game controller, satellite dish, scanner, printer, wireless device, etc. The I/O components 714 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 700. The computing device 700 may be include depth cameras, such as stereoscopic camera systems, infrared camera systems, RGB camera systems, touchscreen technology, and combinations of these, for gesture detection and recognition. Additionally, the computing device 700 may include accelerometers or gyroscopes (e.g., as part of an inertia measurement unit (IMU)) that enable detection of motion. In some examples, the output of the accelerometers or gyroscopes may be used by the computing device 700 to render immersive augmented reality or virtual reality.

The power supply 716 may include a hard-wired power supply, a battery power supply, or a combination thereof. The power supply 716 may provide power to the computing device 700 to enable the components of the computing device 700 to operate.

The presentation component(s) 718 may include a display (e.g., a monitor, a touch screen, a television screen, a heads-up-display (HUD), other display types, or a combination thereof), speakers, and/or other presentation components. The presentation component(s) 718 May receive data from other components (e.g., the GPU(s) 708, the CPU(s) 706, DPUs, etc.), and output the data (e.g., as an image, video, sound, etc.).

### Example Data Center

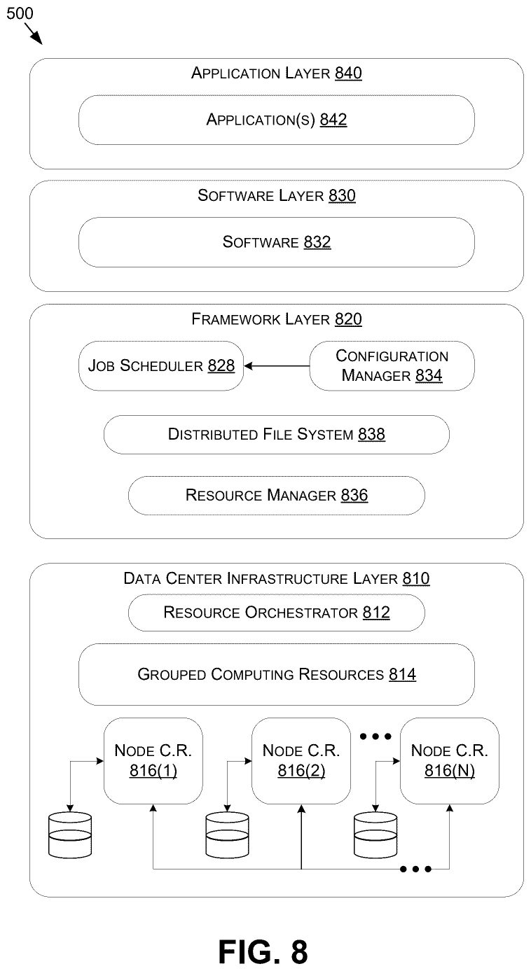

FIG. 8 illustrates an example data center 800 that may be used in at least one embodiments of the present disclosure. The data center 800 may include a data center infrastructure layer 810, a framework layer 820, a software layer 830, and/or an application layer 840.

As shown in FIG. 8, the data center infrastructure layer 810 may include a resource orchestrator 812, grouped computing resources 814, and node computing resources (“node C.R.s”) 816(1)-816(N), where “N” represents any whole, positive integer. In at least one embodiment, node C.R.s 816(1)-816(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 816(1)-816(N) may correspond to a server having one or more of the above-mentioned computing resources. In addition, in some embodiments, the node C.R.s 816(1)-8161(N) may include one or more virtual components, such as vGPUs, vCPUs, and/or the like, and/or one or more of the node C.R.s 816(1)-816(N) may correspond to a virtual machine (VM).

In at least one embodiment, grouped computing resources 814 may include separate groupings of node C.R.s 816 housed within one or more racks (not shown), or many racks housed in data centers at various geographical locations (also not shown). Separate groupings of node C.R.s 816 within grouped computing resources 814 may include grouped compute, network, memory or storage resources that may be configured or allocated to support one or more workloads. In at least one embodiment, several node C.R.s 816 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 812 may configure or otherwise control one or more node C.R.s 816(1)-816(N) and/or grouped computing resources 814. In at least one embodiment, resource orchestrator 812 may include a software design infrastructure (SDI) management entity for the data center 800. The resource orchestrator 812 may include hardware, software, or some combination thereof.

In at least one embodiment, as shown in FIG. 8, framework layer 820 may include a job scheduler 828, a configuration manager 834, a resource manager 836, and/or a distributed file system 838. The framework layer 820 may include a framework to support software 832 of software layer 830 and/or one or more application(s) 842 of application layer 840. The software 832 or application(s) 842 may respectively include web-based service software or applications, such as those provided by Amazon Web Services, Google Cloud and Microsoft Azure. The framework layer 820 may be, but is not limited to, a type of free and open-source software web application framework such as Apache Spark™ (hereinafter “Spark”) that may utilize distributed file system 838 for large-scale data processing (e.g., “big data”). In at least one embodiment, job scheduler 828 may include a Spark driver to facilitate scheduling of workloads supported by various layers of data center 800. The configuration manager 834 may be capable of configuring different layers such as software layer 830 and framework layer 820 including Spark and distributed file system 838 for supporting large-scale data processing. The resource manager 836 may be capable of managing clustered or grouped computing resources mapped to or allocated for support of distributed file system 838 and job scheduler 828. In at least one embodiment, clustered or grouped computing resources may include grouped computing resource 814 at data center infrastructure layer 810. The resource manager 836 may coordinate with resource orchestrator 812 to manage these mapped or allocated computing resources.

In at least one embodiment, software 832 included in software layer 830 may include software used by at least portions of node C.R.s 816(1)-816(N), grouped computing resources 814, and/or distributed file system 838 of framework layer 820. One or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 838 of framework layer 820. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 834, resource manager 836, and resource orchestrator 812 may implement any number and type of self-modifying actions based on any amount and type of data acquired in any technically feasible fashion. Self-modifying actions may relieve a data center operator of data center 800 from making possibly bad configuration decisions and possibly avoiding underutilized and/or poor performing portions of a data center.

The data center 800 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 800. In at least one embodiment, trained or deployed machine learning models corresponding to one or more neural networks may be used to infer or predict information using resources described above with respect to the data center 800 by using weight parameters calculated through one or more training techniques, such as but not limited to those described herein.

In at least one embodiment, the data center 800 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or performing inferencing of information, such as image recognition, speech recognition, or other artificial intelligence services.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 700 of FIG. 7—e.g., each device may include similar components, features, and/or functionality of the computing device(s) 700. In addition, where backend devices (e.g., servers, NAS, etc.) are implemented, the backend devices may be included as part of a data center 800, an example of which is described in more detail herein with respect to FIG. 8.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment- and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 700 described herein with respect to FIG. 7. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. One or more processors comprising:
one or more circuits to:
identify a signed distance field for a circuit layout, at least one sample of the signed distance field comprising a gradient of the signed distance field corresponding to a location of the sample;
identify a set of ridge points in the signed distance field based at least on the gradient of the at least one sample of the signed distance field;
generate a graph data structure using the set of ridge points, at least a subset of the set of ridge points represented as nodes in the graph data structure; and
determine a path for the circuit layout using the nodes of the graph data structure.

2. The one or more processors of claim 1, wherein the one or more circuits are to:
identify the set of ridge points according to a discontinuity of the gradient of at least two samples of the signed distance field.

3. The one or more processors of claim 1, wherein the signed distance field is generated as an image, and wherein the one or more circuits are to:
generate a texture corresponding to the signed distance field that encodes whether at least one pixel in the image corresponds to a ridge point of the set of ridge points.

4. The one or more processors of claim 1, wherein the one or more circuits are to:
receive an indication of a first point and a second point in the signed distance field; and
determine the path from the first point to the second point using the nodes of the graph data structure and the signed distance field.

5. The one or more processors of claim 4, wherein the first point is a first contact of a first component of a circuit layout and the second point is a second contact of a second component of the circuit layout.

6. The one or more processors of claim 4, wherein the one or more circuits are to:
determine the path from the first point to the second point using an A-star function.

7. The one or more processors of claim 1, wherein the one or more circuits are to:
generate the ridge graph by generating an edge between at least two ridge points of the set of ridge points.

8. The one or more processors of claim 1, wherein the gradient comprises a two-dimensional gradient for the signed distance field.

9. The one or more processors of claim 1, wherein the one or more circuits are to:
generate the signed distance field using the plurality of shapes such that a respective border of each shape of the plurality of shapes defined as a zero-isoline.

10. The one or more processors of claim 1, wherein the one or more circuits are comprised in at least one of:
a system implemented at least partially using cloud computing resources;
a system implemented at least partially using one or more microservices;
a control system for an autonomous or semi-autonomous machine;
a perception system for an autonomous or semi-autonomous machine;
a system implemented using a robot;
an aerial system;
a medical system;
a boating system;
a smart area monitoring system;
a system for performing deep learning operations;
a system for performing simulation operations;
a system for generating or presenting virtual reality (VR) content, augmented reality (AR) content, or mixed reality (MR) content;
a system for performing digital twin operations;
a system implemented using an edge device;
a system incorporating one or more virtual machines (VMs);
a system for generating synthetic data;
a system implemented at least partially in a data center;
a system for performing conversational artificial intelligence (AI) operations;
a system for performing generative AI operations;
a system implementing language models;
a system implementing vision language models (VLMs);
a system implementing large language models (LLMs);
a system implementing multi-modal language models;
a system for hosting one or more real-time streaming applications;
a system for performing light transport simulation; or
a system for performing collaborative content creation for 3D assets.

11. A system, comprising:
one or more processors to:
generate a texture storing an augmented signed distance field for a circuit layout comprising a plurality of shapes, at least one pixel of the texture comprising a signed distance value and a gradient of the signed distance field corresponding to a location of the at least one pixel and a corresponding shape of the plurality of shapes;
generate, using the signed distance value and the gradient of the at least one pixel of the texture, a ridge texture having a respective pixel value indicating whether a ridge point is present at the at least one pixel of the texture;
identify an additional point to include in the ridge texture; and
iteratively update, using the gradient of adjacent pixels of the texture the ridge texture to rasterize a line from the additional point to at least one second pixel in the ridge texture.

12. The system of claim 11, wherein the one or more processors are to:
generate a ridge point graph using the ridge texture, wherein the at least one pixel comprises a positive value is represented as a node in the ridge point graph.

13. The system of claim 12, wherein the additional point is represented as a node in the ridge point graph.

14. The system of claim 12, wherein the one or more processors are to:
remove at least one node from the ridge point graph by combining at least two edges in the ridge point graph connected to the at least one node.

15. The system of claim 11, wherein the one or more processors are to:
generate a path from a start point to an end point using the ridge texture.

16. The system of claim 11, wherein the one or more processors are comprised in at least one of:
a system implemented at least partially using cloud computing resources;
a system implemented at least partially using one or more microservices;
a control system for an autonomous or semi-autonomous machine;
a perception system for an autonomous or semi-autonomous machine;
a system implemented using a robot;
an aerial system;
a medical system;
a boating system;
a smart area monitoring system;
a system for performing deep learning operations;
a system for performing simulation operations;
a system for generating or presenting virtual reality (VR) content, augmented reality (AR) content, or mixed reality (MR) content;
a system for performing digital twin operations;
a system implemented using an edge device;
a system incorporating one or more virtual machines (VMs);
a system for generating synthetic data;
a system implemented at least partially in a data center;
a system for performing conversational artificial intelligence (AI) operations;
a system for performing generative AI operations;
a system implementing language models;
a system implementing vision language models (VLMs);
a system implementing large language models (LLMs);
a system implementing multi-modal language models;
a system for hosting one or more real-time streaming applications;
a system for performing light transport simulation; or
a system for performing collaborative content creation for 3D assets.

17. A method, comprising:
identifying, using one or more processors, a signed distance field for a circuit layout, at least one sample of the signed distance field comprising a gradient of the signed distance field corresponding to a location of the sample;
identifying, using the one or more processors, a set of ridge points in the signed distance field based at least on the gradient of the at least one sample of the signed distance field;
generating, using the one or more processors, a graph data structure using the set of ridge points, at least a subset of the set of ridge points represented as nodes in the graph data structure; and
determining, using the one or more processors, a path for the circuit layout using the nodes of the graph data structure.

18. The method of claim 17, further comprising:
identifying, using the one or more processors, the set of ridge points according to a discontinuity of the gradient of at least two samples of the signed distance field.

19. The method of claim 17, wherein the signed distance field is generated as an image, and further comprising:
generating, using the one or more processors, a texture corresponding to the signed distance field that encodes whether at least one pixel in the image corresponds to a ridge point of the set of ridge points.

20. The method of claim 17, further comprising:
receiving, using the one or more processors, an indication of a first point and a second point in the signed distance field; and
determining, using the one or more processors, the path from the first point to the second point using the nodes of the graph data structure and the signed distance field.
